(19) United States
(12) Patent Application Publication
(10) Pub. No.: US 2025/0118831 A1
(43) Pub. Date: Apr. 10, 2025

(54) Swappable Battery Modules Comprising Immersion-Thermally Controlled Prismatic Battery Cells and Methods of Fabricating Thereof

(71) Applicant: DIMAAG-AI, Inc., Fremont, CA (US)

(72) Inventors: Ian Wright, Woodside, CA (US); Roatchanatam Anattasakul, Fremont, CA (US); Mahmoodreza Forootan, Fremont, CA (US); Brian Graf, Fremont, CA (US); Irfan Nadiadi, Fremont, CA (US)

(21) Appl. No.: 18/984,353

(22) Filed: Dec. 17, 2024

Related U.S. Application Data
(63) Continuation-in-part of application No. 18/820,930, filed on Aug. 30, 2024.
Application No. 18/820,930 is a continuation-in-part of application No. 18/449,507, filed on Aug. 14, 2023.
Application No. 18/449,507 is a continuation of application No. 18/182,912, filed on Mar. 13, 2023, now Pat. No. 11,784,369.
(60) Provisional application No. 63/489,488, filed on Mar. 10, 2023.

(51) Int. Cl. H01M 10/6568; B60L 53/80; H01M 10/42; H01M 10/613; H01M 10/647; H01M 50/209; H01M 50/244; H01M 50/258; H01M 50/367; H01M 50/507; H01M 50/55; H05K 7/20

(52) U.S. Cl. CPC H01M 10/6568; B60L 53/80; H01M 10/613; H01M 10/647; H01M 50/209; H01M 50/244; H01M 50/258; H01M 50/367; H01M 50/507; H01M 50/55; H05K 7/20236; H01M 2010/4271

(57) ABSTRACT

Described herein are swappable battery modules comprising immersion-thermally controlled prismatic battery cells and methods of operating thereof. A method comprises positioning a swappable battery module on a battery dock comprising dock fluidic ports and sliding the swappable battery module to the dock fluidic ports until these dock's ports are fluidically coupled with the module's fluidic ports. Specifically, the dock comprises an enclosure and a module support rail slidably coupling the swappable battery module and the enclosure. The module support rail comprises a rail base, a first slider, a second slider, and a lever-based unit, interconnecting the rail base and both sliders. The rail base is fixed to the enclosure, while the second slider is detachably coupled to the module. The two sliders move at different speeds or at the same speed relative to the dock base depending on the proximity of the first end plate to the dock base.

### CROSS-REFERENCE TO RELATED APPLICATIONS

This application is a continuation-in-part of U.S. patent application Ser. No. 18/820,930, filed on 2024 Aug. 30 (Docket No. DIMAP017USX1), which is a continuation-in-part of U.S. patent application Ser. No. 18/449,507, filed on 2023 Aug. 14 (Docket No. DIMAP017USC1), which is a continuation of U.S. patent application Ser. No. 18/182,912, filed on 2023 Mar. 13, issued as U.S. Pat. No. 11,784,369 on 2023 Oct. 10 (Docket No. DIMAP017US), which claims the benefit under 35 U.S.C. § 119(e) of U.S. Provisional Patent Application No. 63/489,488, filed on 2023 Mar. 10 (Docket No. DIMAP017P), all of which are incorporated herein by reference in their entirety for all purposes.

### BACKGROUND

Electric vehicles are propelled using electric motors powered by battery packs. Each battery pack can include one or more swappable battery modules, each comprising one or more battery cells. These cells can be connected in series and/or parallel and controlled by a battery management system. While the operating temperature of battery cells depends on various materials used to fabricate these cells (e.g., electrolyte solvents), most battery cells are designed to operate in the 0-60° C. range. It should be noted that battery cells can be very sensitive to their operating temperatures. For example, the power rating of battery cells can drop quickly with the temperature (caused by lower ionic mobility). At the same time, battery cells degrade faster and can potentially enter unsafe conditions when operated at high temperatures.

In addition to various environmental conditions that can change cells' operating temperature, battery cells can generate considerable heat while charging and discharging, especially at high rates (that can be desirable for many applications). For example, Joule heating caused by cells' internal resistance is one of the largest contributors. Other contributors include but are not limited to electrode reactions and entropic heat generation caused by the insertion and de-insertion of lithium ions in and out of the electrodes. To maintain optimum operating temperatures, the heat must be removed from the battery cells as this heat is being generated within the cells. It should be noted that other components of battery packs (e.g., bus bars that interconnect battery cells) can also cause heating and should be cooled whenever possible.

Liquid cooling or, more generally, liquid-based thermal management of battery cells is beneficial in comparison to, e.g., air cooling because of the large heat capacities and heat transfer coefficient of many liquids in comparison to air. However, controlling the distribution of liquid within battery packs can be challenging. For example, most liquid-cooled battery packs have battery cells isolated from liquid passages thereby preventing any direct contact between the cells and thermal fluid and relying on various heat-transferring components positioned in between. Furthermore, many liquid-cooled battery packs utilize cylindrical cells (e.g., 18650 cells) because of their small factor and ease of cooling (e.g., by thermal coupling to cell bottoms). However, battery packs with cylindrical cells tend to have lower energy density because of their inherent packing density limitations. Additionally, most battery cooling systems focus on cooling batteries and ignore bus bar cooling. At the same time, the bus bar cooling can prevent the overheating of bus bars and even allow the use of bus bars with smaller cross-sections (for a given current). Finally, liquid-cooled swappable battery modules are generally stationary (e.g., permanently positioned on electric vehicles). At the same time, many applications (e.g., smaller electric vehicles) can benefit from swappable batteries that, for example, can be charged remotely and that can also be liquid-cooled (e.g., while on the vehicle and/or on the charger). However, forming/severing the liquid connections to a module in a fast and efficient manner can be challenging.

What is needed are new swappable battery modules comprising immersion-thermally controlled prismatic battery cells and methods of fabricating thereof.

### SUMMARY

Described herein are swappable battery modules comprising immersion-thermally controlled prismatic battery cells and methods of operating thereof. A method comprises positioning a swappable battery module on a battery dock comprising dock fluidic ports and sliding the swappable battery module to the dock fluidic ports until these dock's ports are fluidically coupled with the module's fluidic ports. Specifically, the dock comprises an enclosure and a module support rail slidably coupling the swappable battery module and the enclosure. The module support rail comprises a rail base, a first slider, a second slider, and a lever-based unit, interconnecting the rail base and both sliders. The rail base is fixed to the enclosure, while the second slider is detachably coupled to the module. The two sliders move at different speeds or at the same speed relative to the dock base depending on the proximity of the first end plate to the dock base.

Clause 1. A method of operating a swappable battery module comprising a first electrical terminal, a second electrical terminal, a first fluidic port, and a second fluidic port, the method comprising: positioning the swappable battery module on a battery dock comprising an enclosure, a module support rail slidably coupling the swappable battery module and the enclosure, a dock base attached to the enclosure and comprising dock electric terminals; and sliding the swappable battery module on the module support rail toward the dock base until the first electrical terminal and the second electrical terminal are connected with the dock electric terminals, wherein: the module support rail comprises a rail base, a first slider, and a second slider, the rail base is fixed to the enclosure, the second slider is detachably coupled to the swappable battery module, and the first slider and the second slider move at different speeds or at a same speed relative to the dock base and the rail base depending on proximity of the swappable battery module to the dock base.

Clause 2. The method of clause 1, wherein the rail base comprises a rail-base slot defined by an engagement slot section and an extraction slot section, extending perpendicular to the engagement slot section.

Clause 3. The method of clause 2, wherein the engagement slot section comprises end points, operable as positive stops and defines a closest position between the swappable battery module and the dock base.

Clause 4. The method of clause 2, wherein: the module support rail further comprises a lever-based unit comprising bushings slidably fit into the rail-base slot, when the bushings are in the engagement slot section, the first slider moves faster than the second slider, and when the bushings are in the extraction slot section, the first slider and the second slider move at the same speed.

Clause 5. The method of clause 4, wherein, when the bushings are in the engagement slot section, the first slider moves at least twice as fast as the second slider.

Clause 6. The method of clause 4, wherein: the lever-based unit comprises a first lever set and a second lever set, the first lever set is connected to the bushings at the first end, pivotably connected to the first slider at a midpoint, and pivotably connected to the second lever set at a second end of the first lever set, opposite to the first end, and the second lever set is pivotably connected to the first lever set and the first slider at opposite ends of the second lever set.

Clause 7. The method of clause 6, wherein: the first lever set comprises a first lever and a second lever, each of the first lever and the second lever comprises a first lever unit and a second lever unit spaced apart from each other and forming a gap c, and the rail base partially extends into the gap c of each of the first lever and the second lever thereby restricting out-of-plane movement of each of the first lever and the second lever relative to the rail base.

Clause 8. The method of clause 7, wherein each of the first lever and a second lever rotatably support one of the bushings.

Clause 9. The method of clause 8, wherein each of the bushings comprises: a stem protruding into round openings in each of the first lever and second lever, and a collar that has a larger diameter than the stem and that extends into the gap between the first lever unit and the second lever unit.

Clause 10. The method of clause 9, wherein: each of the first lever and the second lever comprises a band positioned between the first lever unit and the second lever unit and maintaining the gap c between the first lever unit and the second lever unit, and the band surrounds a corresponding one of the bushings.

Clause 11. The method of clause 1, wherein: the module support rail further comprises a locking mechanism configured to switch between a locked state and an unlocked state, in the locked state, the locking mechanism allows the first slider to slide relative to the rail base, and in the unlocked state, the locking mechanism prevents the first slider from sliding relative to the rail base.

Clause 12. The method of clause 11, wherein: the locking mechanism comprises a lock support, a pivotable lock supported by the lock support, and an actuator configured to pivot the pivotable lock between the locked state and the unlocked state, the rail base comprises a locking cavity facing the first slider, in the locked state, the pivotable lock extends into the locking cavity, and in the unlocked state, the pivotable lock is pulled from the locking cavity.

Clause 13. The method of clause 12, wherein the locking mechanism comprises a spring that biases the locking mechanism into the locked state.

Clause 14. The method of clause 11, wherein: the module support rail comprises a rail handle, the locking mechanism comprises an actuator, connected to the rail handle, and pulling the rail handle, away from the dock base, switches the locking mechanism from the locked state to the unlocked state.

Clause 15. The method of clause 1, wherein: the swappable battery module comprises a first end plate and a second end plate positioned on opposite sides of the swappable battery module, and each of the first end plate and the second end plate comprises four elastic bumpers that directly interface the enclosure when the first electrical terminal and the second electrical terminal are connected with the dock electric terminals.

Clause 16. The method of clause 15, wherein: the enclosure comprises bolsters directly interfacing at least two of the elastic bumpers on each of the first end plate and the second end plate, and the bolsters are slidable along an axis parallel to a sliding direction of the swappable battery module on the module support rail.

Clause 17. The method of clause 16, wherein the bolsters are biased a direction away from the dock base.

Clause 18. The method of clause 15, wherein: the dock base comprises a set of flexible members, a connector-support portion, and an enclosure-attachment portion, movably attached to the enclosure-attachment portion by the set of flexible members, the connector-support portion supports each of the first electrical terminal, the second electrical terminal, the first fluidic port, and the second fluidic port, and the enclosure-attachment portion is rigidly attached to the enclosure.

Clause 19. The method of clause 18, wherein each flexible member in the set of flexible members is a leaf spring.

Clause 20. The method of clause 15, wherein: the battery dock further comprises dock fluidic ports that are fluidically coupled with the first fluidic port and the second fluidic port when the first electrical terminal and the second electrical terminal are connected with the dock electric terminals.

### BRIEF DESCRIPTION OF THE DRAWINGS

FIG. 1 is a block diagram of a system comprising an electric vehicle, a charger, and a swappable battery module that can be interchangeably connected to either the electric vehicle or the charger, in accordance with some examples.

FIG. 2A is a block diagram of a swappable battery module, in accordance with some examples.

FIG. 2B is a schematic illustration of a swappable battery module comprising immersion-thermally controlled battery cells, in accordance with some examples.

FIG. 2C is a schematic perspective view of a stack of prismatic battery cells for use in a swappable battery module, in accordance with some examples.

FIG. 2D is a schematic perspective view of the prismatic battery cells in FIG. 2C with three sets of bus bars attached to the cells, in accordance with some examples.

FIG. 2E is a schematic expanded view of FIG. 2D illustrating two disjoined bus bar components, in accordance with some examples.

FIG. 2F is a schematic top view of the prismatic battery cells in FIG. 2C with two sets of bus bars (and no return bus bar) attached to the cells, in accordance with some examples.

FIG. 2G is a schematic cross-sectional view of a swappable battery module illustrating fluidic channels formed by the tubular enclosure and cells, in accordance with some examples.

FIGS. 2H and 2I are schematic views of a swappable battery module illustrating fluidic pathways through the module, in accordance with some examples.

FIGS. 2J and 2K are schematic perspective front and back views of a first end plate, in accordance with some examples.

FIG. 2L is a schematic perspective view of a second end plate, in accordance with some examples.

FIGS. 3A and 3B are schematic cross-sectional side views of a fluidic coupling comprising a first component and a second component, one of which can be operable as a fluidic port of a swappable battery module, in a coupled state (FIG. 3A) and a decoupled state (FIG. 3B) in accordance with some examples.

FIG. 4 is a process flowchart of a method for operating a swappable battery module, in accordance with some examples.

FIGS. 5A-5F are schematic cross-sectional side views of a fluidic coupling at different stages while decoupling the first component from the second component, in accordance with some examples.

FIGS. 5G-5I are schematic cross-sectional side views of additional examples of a fluidic coupling at different stages while decoupling the first component from the second component.

FIG. 5J is a perspective view of a first spool, in accordance with some examples.

FIG. 5K is a perspective view of a second spool, in accordance with some examples.

FIGS. 6A and 6B are schematic views of a charger and one swappable battery module connected to the charger, in accordance with some examples.

FIGS. 6C-6E are schematic side views of a charger at various stages while connecting a swappable battery module to the charger, in accordance with some examples.

FIGS. 7A-7C are schematic side views of a charger supporting six swappable battery modules, in accordance with some examples.

FIG. 7D is a bottom perspective view of a swappable battery module removed from the charger and attached to a module support rail, in accordance with some examples.

FIGS. 8A and 8B are two perspective views of a module support rail for supporting a swappable battery module in a charger, in accordance with some examples.

FIGS. 9A-9E illustrate bottom views of a module support rail and a swappable battery module at different stages while removing the swappable battery module from a charger, in accordance with some examples.

FIGS. 10A-10B are bottom partial views of a slider mechanism illustrating a first lever set supporting bushings, in accordance with some examples.

FIG. 10C is a cross-sectional view of the first lever set supporting bushings, in accordance with some examples.

FIGS. 11A-11E are top views of a slider mechanism with a locking mechanism in different positions, in accordance with some examples.

FIGS. 12A-12B are side schematic views of the elastic bumpers (of the swappable battery module) engaging the bolsters of the enclosure when the swappable battery module is inserted into the enclosure, in accordance with some examples.

FIG. 12C is a schematic perspective view of the enclosure illustrating the positions of different bolsters, in accordance with some examples.

FIGS. 13A-13D are front schematic views of a dock base comprising a connector-support portion movably supported relative to the enclosure-attachment portion by a set of flexible members, in accordance with some examples.

### DETAILED DESCRIPTION

In the following description, numerous specific details are outlined to provide a thorough understanding of the present invention. The present invention may be practiced without some or all of these specific details. In other instances, well-known process operations have not been described in detail to avoid obscuring the present invention. While the invention will be described in conjunction with the specific examples, it will be understood that it is not intended to limit the invention to the examples.

### Introduction

As noted above, battery cells can be very sensitive to operating temperatures. At the same time, these temperatures can be influenced by the environment and/or by the cells' operation (e.g., self-heating during fast charge/discharge). Liquid-based thermal management provides efficient ways to control the temperature of battery cells. However, the thermal coupling of battery cells and thermal fluid can be challenging. The immersion cooling of battery cells brings battery cells in direct contact with thermal fluids, which is beneficial for thermal transfer (in comparison to positioning intermediate structures between the cells and thermal fluids, e.g., to enclose the thermal fluid). The key challenges include controlling the distribution and flow of thermal fluids around battery cells and other components (e.g., bus bars).

Described herein are swappable battery modules comprising immersion-thermally controlled prismatic battery cells and methods of operating thereof. Specifically, each battery cell comes in direct contact with a thermal fluid (e.g., transformer oil) at multiple locations, e.g., two locations on the first surface of these battery cells and two additional locations on the second surface, opposite of the first surface. Furthermore, the thermal fluid is circulated in such a way that all experience substantially the same heat transfer driven by the temperature difference between the cells and fluid. Furthermore, even when the thermal fluid is not circulated, the fluid remaining in the swappable battery module provides an additional thermal mass and thermal pathways between the cells and other components of the swappable battery modules. For example, at certain operating conditions (e.g., discharge/charge rates of at or less than 5C, at or less than 2C, or even at or less than 1C), no circulation of the thermal fluid may be provided. Specifically, no fluid circulating may be provided while a batter module is positioned on a vehicle. However, at higher discharge/charge rates (e.g., at or greater than 5C, at or greater than 8C, or even at or greater than 10C), the thermal fluid can be circulated through the module (e.g., when the module is connected to a charger thereby enabling high charge rates). Specifically, the thermal fluid may be circulated through the swappable battery module as well as between the module and an external cooling system, wherein the thermal fluid is cooled before being returned to the module. It should be noted that immersion-thermally control may involve cooling and/or heating.

In some examples, battery cells are glued together for the structural integrity of the resulting swappable battery module. The adhesive layers provided between the cells can also be used for the electrical isolation of battery cells and, to some extent, for thermal isolation of the cells (both of which are safety measures). Furthermore, the direct attachment of the battery cells effectively provides some internal structural support (e.g., a module skeleton) and reduces the structural requirements from the external components, thereby reducing the weight/size of these components (and increasing the gravimetric/volumetric capacity of the module). External support is provided by an enclosure.

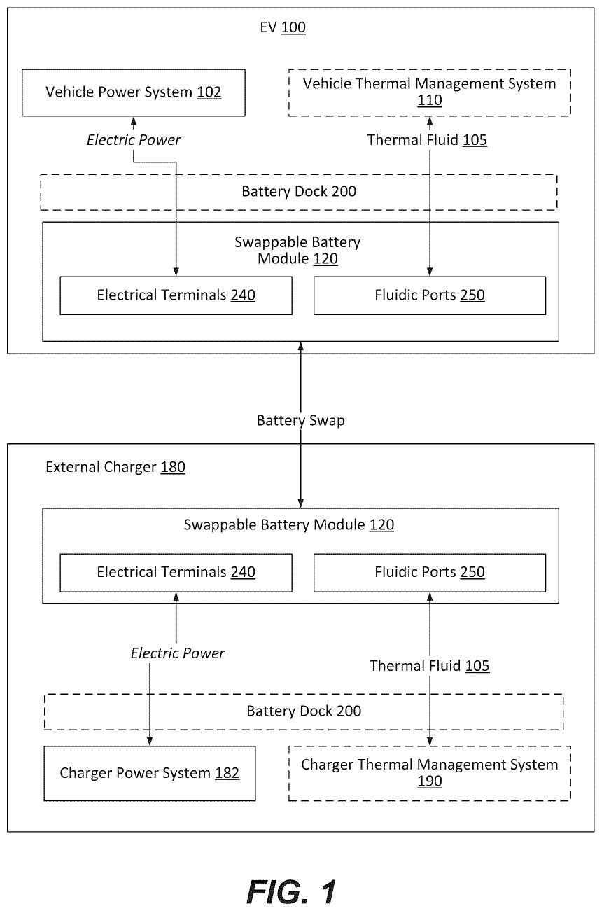

Swappable battery modules described herein can be used to power electric vehicles and can be charged using chargers. FIG. 1 is a schematic block diagram illustrating swappable battery module 120 being swapped between electric vehicle 100 (to power electric vehicle 100) and external charger 180 (to recharge swappable battery module 120). Hence swappable battery module 120 may be also referred to as a swappable battery module 120. For purposes of this disclosure, the terms “swappable battery module” and “swappable battery module” are used interchangeably. Furthermore, the swappable battery module 120 may also be referred to as an immersion-thermally controlled swappable battery module since the cells within the module are in direct contact with the thermal fluid as described below. The connection between the swappable battery module 120 and either the electric vehicle 100 or the external charger 180 may be formed using a battery dock 200, which may be a part of the electric vehicle 100 and/or a part of the external charger 180. In other words, one or both of the electric vehicle 100 or the external charger 180 may be equipped with a separate battery dock 200 that forms electric connections and, in some examples, fluidic connections with the swappable battery module 120.

While on electric vehicle 100, swappable battery module 120 is electrically connected to vehicle power system 102, e.g., inverters, electric motors, and other like devices. Various types of electric vehicles 100 (e.g., tractors, rugged terrain vehicles (RTVs), all-terrain vehicles (ATVs), industrial electric vehicles such as loaders, forklifts, and the like) are within the scope. In some examples, swappable battery module 120 can also be fluidically connected to vehicle thermal management system 110, which allows circulating thermal fluid 105 between vehicle thermal management system 110 and swappable battery module 120. Vehicle thermal management system 110 is optional and, in some examples, swappable battery module 120 does not form any fluidic connections to any systems on electric vehicle 100. When such a connection is formed, the circulation of thermal fluid 105 can be used to control the temperature of swappable battery module 120 or, more specifically, the temperature of the battery cells forming this swappable battery module 120. For example, electric vehicle 100 (e.g., snowmobiles, ATVs) can be operated at environmental temperatures that are outside of the desired cell temperature range. In the same or other examples, the power demand from vehicle power system 102 can cause significant heating of the battery cells (e.g., exceeding the environmental cooling rate of the swappable battery module 120). Vehicle thermal management system 110 can be configured to provide thermal fluid 105 at a desired temperature range (e.g., between 10° C. and) 30° to assist with cooling and/or heating of swappable battery module 120. In some examples, vehicle thermal management system 110 is equipped with one of a heat pump, a heater, a radiator, and the like.

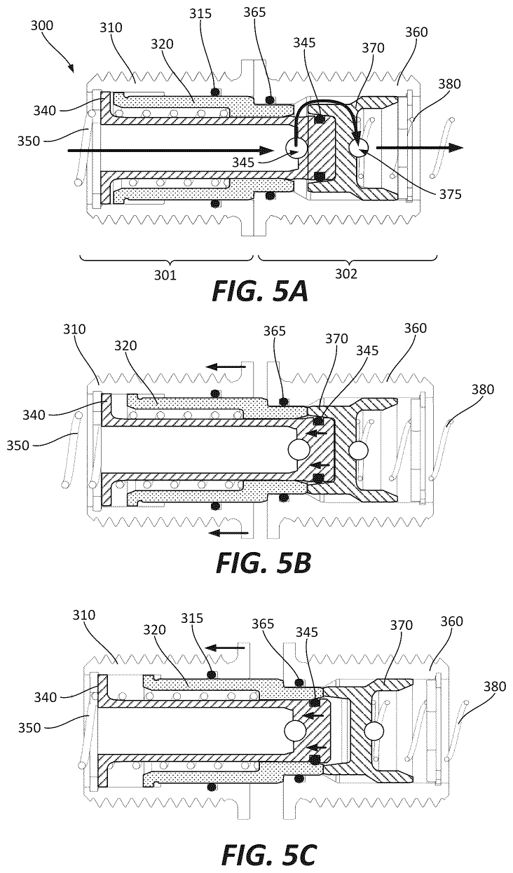

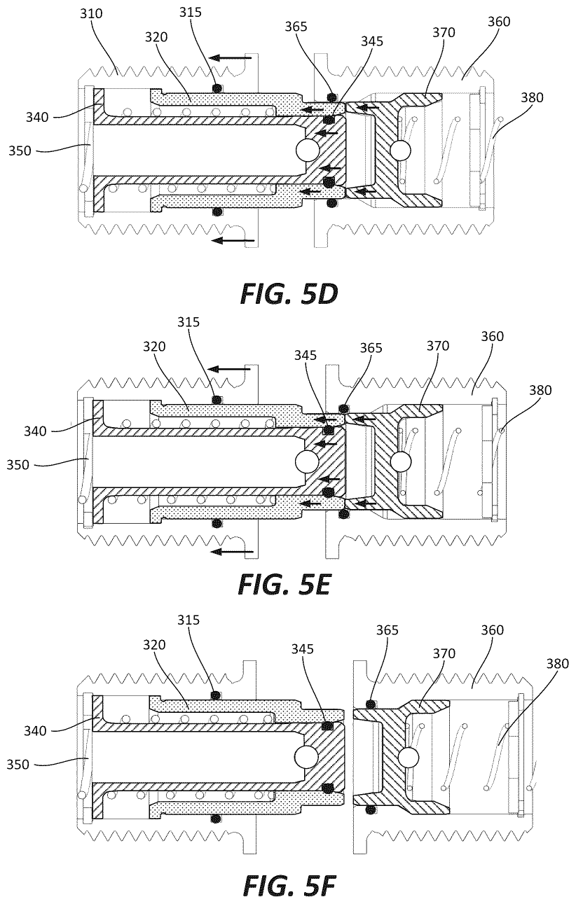

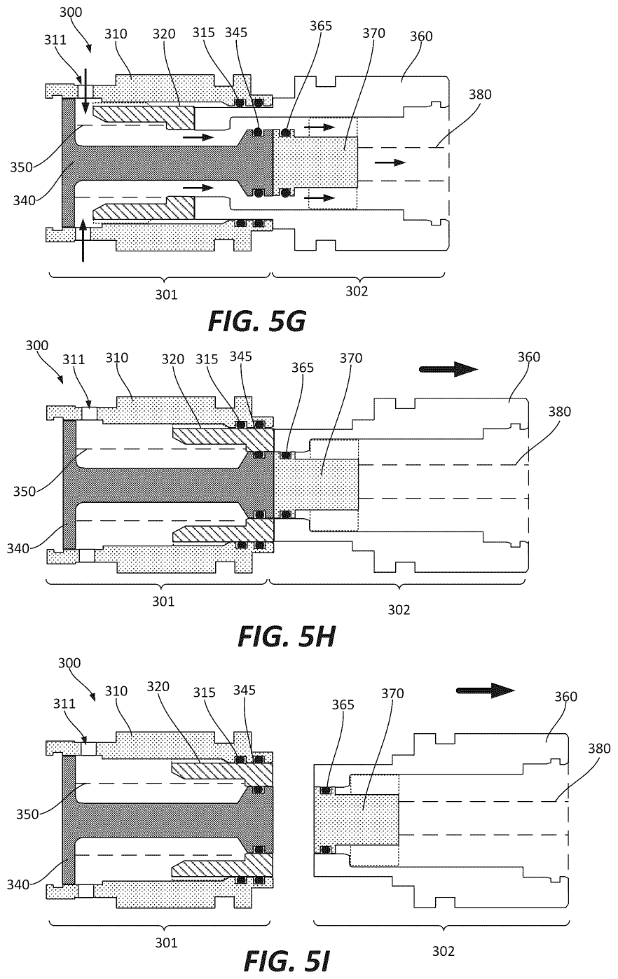

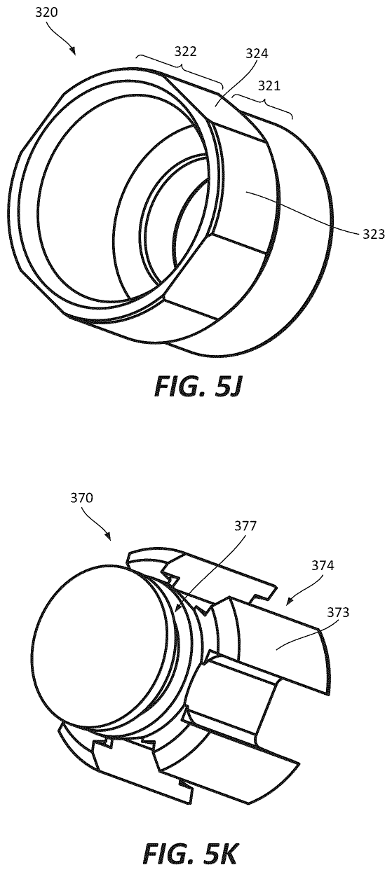

While positioned on the external charger 180, the swappable battery module 120 is electrically connected to the charger power system 182. In some examples, swappable battery module 120 can also be fluidically connected to charger thermal management system 190. Charger thermal management system 190 is optional and, in some examples, the swappable battery module 120 does not form any fluidic connections to any systems on the external charger 180. When such a connection is formed, this connection allows circulating thermal fluid 105 between the charger thermal management system 190 and the swappable battery module 120. As noted above, this circulation of thermal fluid 105 can be used to control the temperature of the swappable battery module 120 or, more specifically, the temperature of the battery cells forming this swappable battery module 120. In addition to environmental temperature considerations, this circulation allows the use of high charge rates (e.g., greater than 2C, greater than 5C, and even as high as 10C or greater) without the risk of overheating the cells. Charge currents (similar to discharge currents) caused the internal cell heating. The circulation of thermal fluid 105 allows for the efficient removal of this generated heat thereby allowing higher charge rates and faster charging. In some examples, the charger thermal management system 190 is equipped with one of a heat pump, a heater, a radiator, and the like. Examples of fluidic connections are described below with reference to FIGS. 5A-5F.

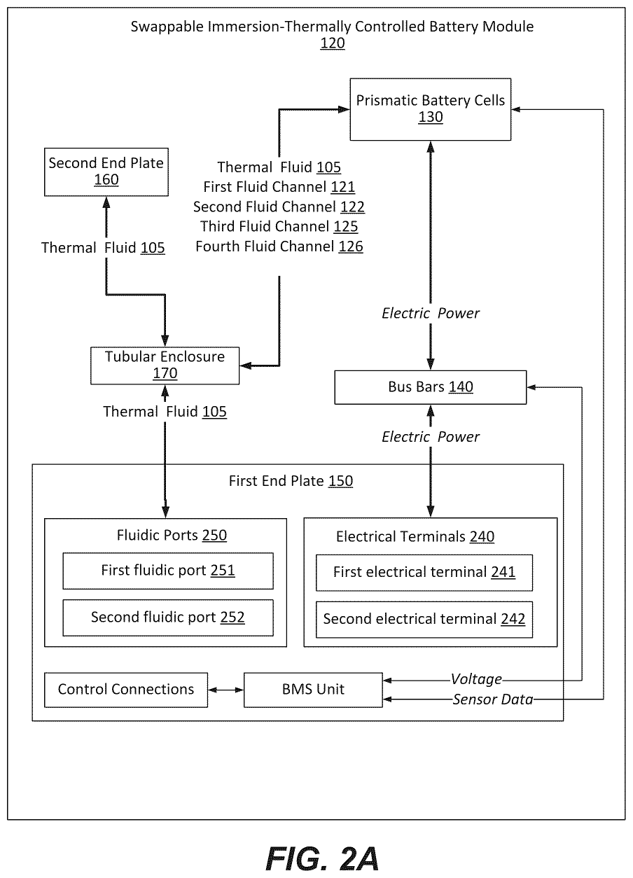

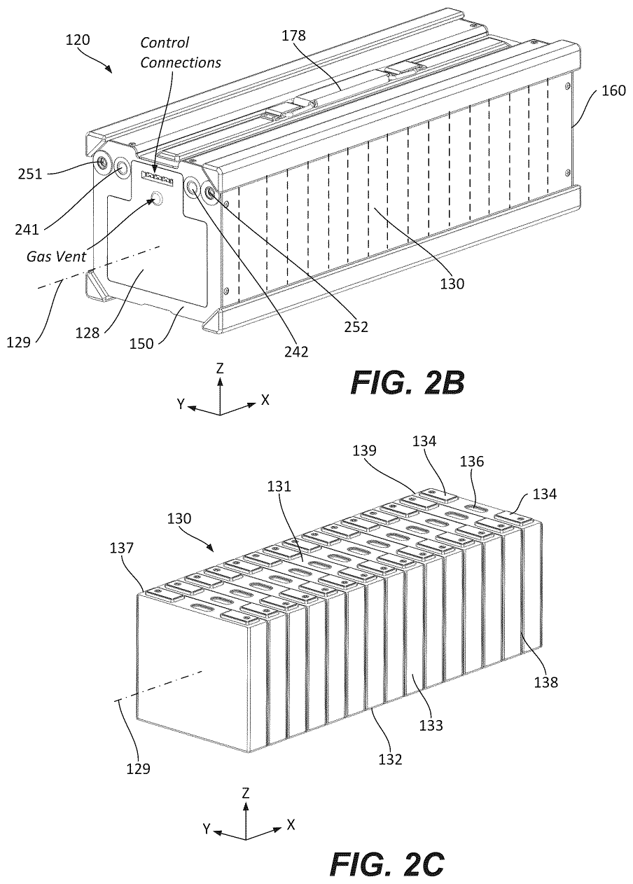

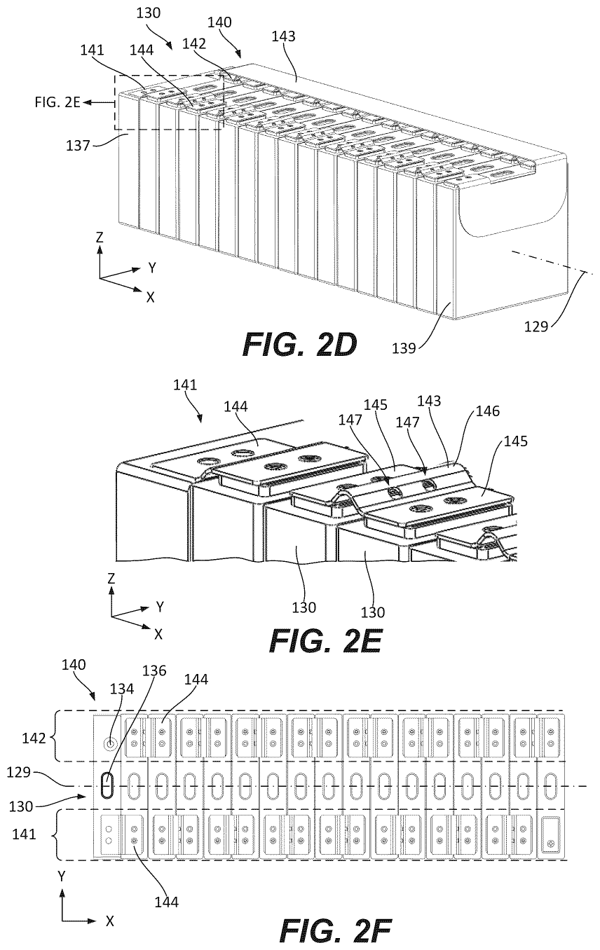

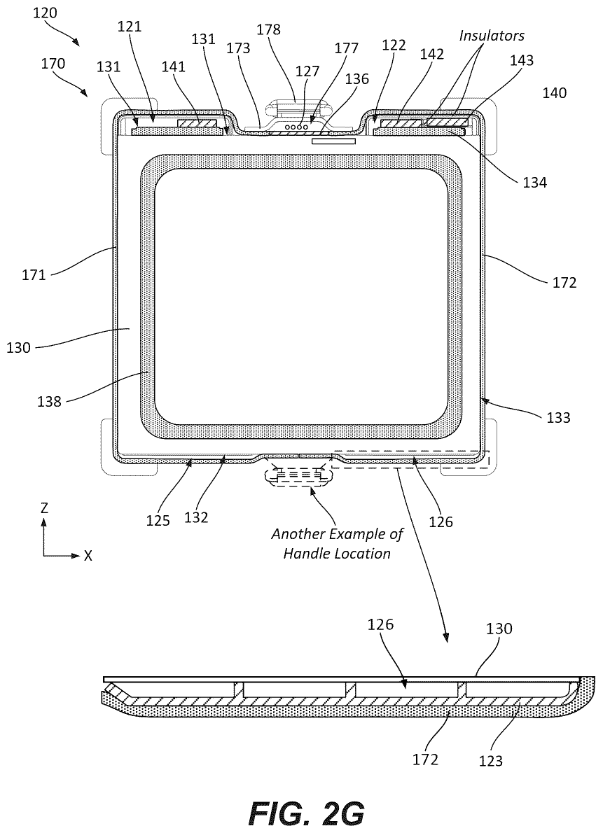

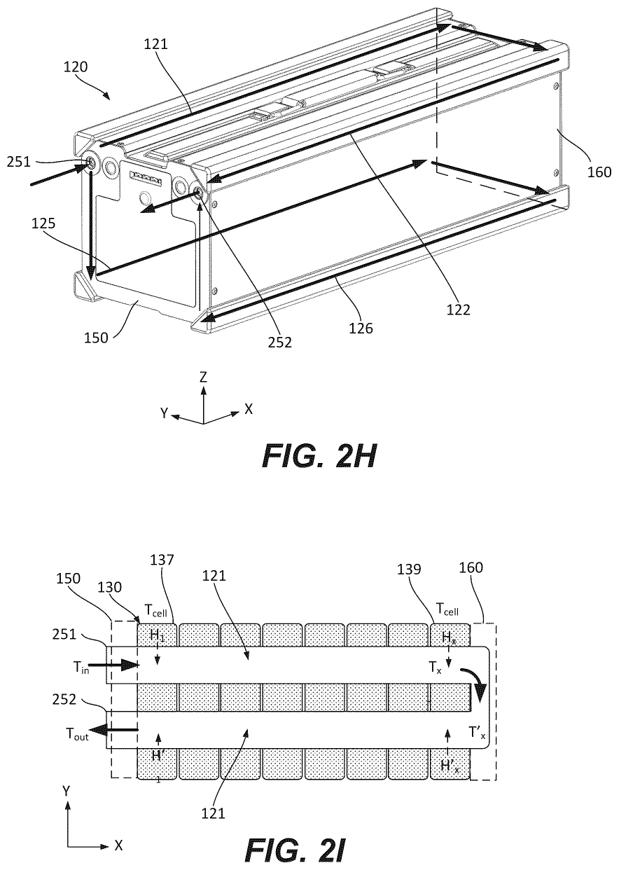

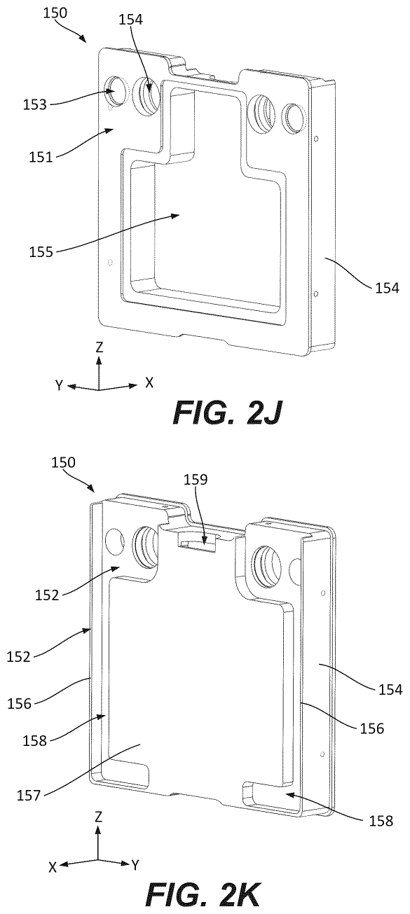

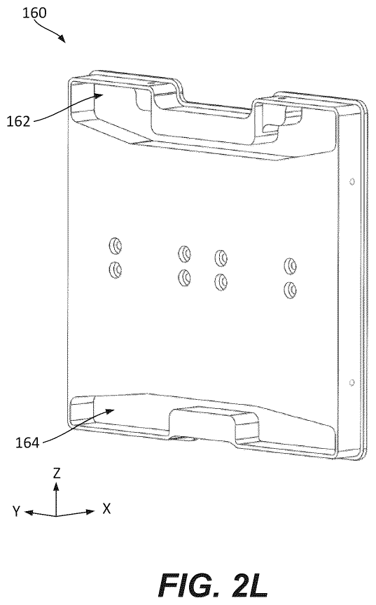

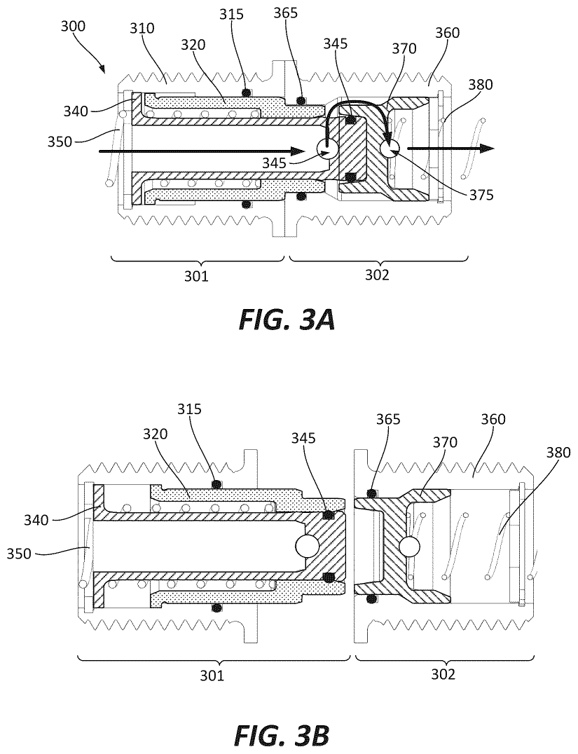

The swappable battery module 120 comprises electrical terminals 240 to form the above-referenced electrical connections. The same set of electrical terminals 240 is used for connection to both vehicle power system 102 and charger power system 182. Furthermore, the swappable battery module 120 comprises fluidic ports 250 to form the above-referenced fluidic connections, e.g., to at least one of the vehicle thermal management system 110 and charger thermal management system 190. These and other features of swappable battery module 120 will now be described with reference to FIGS. 2A-2L and FIG. 3A-3B.

### Examples of Swappable Immersion-Thermally Controlled Swappable Battery Modules

FIG. 2A is a block diagram of swappable battery module 120, illustrating various module components as well as mechanical and functional connections among these components, in accordance with some examples. FIG. 2B is a schematic perspective view of swappable battery module 120 in FIG. 2A. Swappable battery module 120 comprises immersion-thermally controlled battery cells 130 forming one or more stacks inside swappable battery module 120. Specifically, in the view of FIG. 2B, prismatic battery cells 130 (schematically identified using dashed lines) are hidden by other components such as tubular enclosure 170, first end plate 150, and second end plate 160. A combination of tubular enclosure 170, first end plate 150, and second end plate 160 enclose prismatic battery cells 130 and isolate prismatic battery cells 130 from the environment. Furthermore, this combination of tubular enclosure 170, first end plate 150, and second end plate 160 provide the immersion thermal control to prismatic battery cells 130 by containing thermal fluid 105 within various fluid channels formed by these components and prismatic battery cells 130 as further described below.

FIG. 2C is a schematic perspective view of a stack of prismatic battery cells 130, in accordance with some examples. Specifically, tubular enclosure 170, first end plate 150, and second end plate 160 are not shown in FIG. 2C. One having ordinary skill in the art would understand that any number of cells can be used in one swappable battery module 120. Battery cells 130 used in swappable battery module 120 are prismatic, rather than cylindrical. Prismatic battery cells 130 can be packed more compactly (with fewer spaces in between cells) within swappable battery module 120 resulting in a higher density of swappable battery module 120. For purposes of this description, a prismatic battery cell is defined as a cell having the shape of a rectangular prism (as opposed to a cylinder). As such, a prismatic battery cell has three distinct dimensions: (a) height, (b) width, and (c) thickness. In some examples, the height of prismatic battery cell 130 (used in swappable battery module 120) is between 50 millimeters and 200 millimeters or, more specifically, between 75 millimeters and 125 millimeters. In the same or other examples, the width of prismatic battery cell 130 (used in swappable battery module 120) is between 50 millimeters and 200 millimeters or, more specifically, between 75 millimeters and 125 millimeters. In some examples, the thickness of prismatic battery cell 130 (used in swappable battery module 120) is between 5 millimeters and 50 millimeters or, more specifically, between 10 millimeters and 30 millimeters. The number and size of battery cells 130 also define the size and weight of swappable battery module 120. In some examples, swappable battery module 120 has a weight of between 5 kilograms and 50 kilograms or, more specifically, between 10 kilograms and 40 kilograms, such as between 15 kilograms and 30 kilograms. While a heavier module can provide more charge energy, it is much harder to handle and swap heavier modules. In general, the weight of swappable battery module 120 is selected to be swappable by a human.

Prismatic battery cells 130 can be of various chemistry types, e.g., nickel-manganese-cobalt (NMC), lithium iron phosphate (LFP), and lithium titanate (LTO), at least based on the composition of positive electrodes. For example, lithium titanate (LTO) cells can support high charge-discharge rates, which may be particularly useful for industrial applications such as electric tractors, loaders, and the like.

Referring to FIGS. 2B and 2C, prismatic battery cells 130 are stacked along primary axis 129 of the swappable battery module 120 (which extends substantially parallel to the X-axis in these figures). While FIG. 2C illustrates one cell stack, the same swappable battery module 120 may include multiple different cell stacks (e.g., positioned next to each other). Prismatic battery cells 130 comprise first surfaces 131, second surfaces 132 opposite to first surfaces 131, and side surfaces 133 extending between first surfaces 131 and second surfaces 132. For example, each first surface 131, second surface 132, and side surface 133 can be substantially parallel to primary axis 129. In some examples, each of prismatic battery cells 130 has a height, length, and thickness such that the thickness is less than the height and less than the length and such that the thickness is parallel to primary axis 129 of the swappable battery module 120. Prismatic battery cells 130 can be stacked along their thicknesses.

Prismatic battery cells 130 also comprise cell terminals 134 positioned on first surfaces 131. Cell terminals 134 are used to form electrical connections to prismatic battery cells 130. In some examples, cell terminals 134 are isolated from the other external components (e.g., the case, lid) of prismatic battery cells 130 such that these components are neutral. In some examples, prismatic battery cells 130 comprise pressure-release burst valves 136 configured to release gases from the interior of prismatic battery cells 130 when the pressure inside prismatic battery cells 130 exceeds a set threshold. In more specific examples, pressure-release burst valve 136 of each prismatic battery cell 130 is positioned between cell terminals 134 of that cell.

Referring to FIGS. 2C and 2I, in some examples, two adjacent prismatic battery cells 130 are mechanically interconnected by an adhesive layer 138 extending between prismatic battery cells 130 in each adjacent pair. Some examples of adhesive layer 138 include but are not limited to epoxy and polyurethane. The thickness of adhesive layer 138 can be used to accommodate variations in the cell thicknesses. For example, a pair of thin cells may have a thicker adhesive layer, while a pair of thick cells may have a thinner adhesive layer, such that the combined thickness is the same regardless of the cell thicknesses. Furthermore, flexible adhesives can be compressible and used to accommodate cell swelling (if any) during the operation of swappable battery module 120. In some examples, adhesive layers 138 also provide electrical insulations between adjacent cells (e.g., even though the sides of battery cells 130 can be substantially neutral). In these examples, adhesive layers 138 are continuous sheets extending between battery cells 130 to tubular enclosure 170. Alternatively, adhesive layers 138 have an annulus shape, e.g., as shown in FIG. 2I to accommodate swelling of prismatic battery cells 130 that tend to swell more in the center/away from the edges.

Adhesive layers 138 provide attachment/bonding between prismatic battery cells 130 in the set adding to the overall structural integrity of swappable battery module 120. In other words, a combination of prismatic battery cells 130 and adhesive layers 138 is operable as an internal structural element (which can be referred to as a “skeleton”) of the swappable battery module 120. Other components of swappable battery module 120, e.g., first end plate 150, second end plate 160, and tubular enclosure 170 are operable as an internal structural element (“exoskeleton”). Furthermore, adhesive layers 138 provide electrical isolation and, in some examples, thermal isolation of adjacent prismatic battery cells 130. While the cases of prismatic battery cells 130 can be neutral, the electrical isolation can help to improve the overall module safety (e.g., when internal shorts develop in one or more prismatic battery cells 130).

Referring to FIGS. 2D-2E, swappable battery module 120 comprises bus bars 140 interconnecting cell terminals 134. Bus bars 140 can be made from copper, aluminum, nickel, and other suitable conductive materials. While FIGS. 2D and 2F illustrate one example of cell connections (i.e., 17s connection scheme, in which each 17 prismatic battery cells 130 are interconnected in series), other examples are also within the scope. The connection scheme depends on the required voltage output of swappable battery module 120 and other like factors.

In some examples, bus bars 140 comprise a plurality of disjoined components 144, forming first bus-bar row 141 and second bus-bar row 142, e.g., as shown in FIG. 2E where return bus bar 143 is not shown/hidden). Furthermore, bus bars 140 can include return bus bar 143, used for positioning both electric terminals of the swappable battery module 120 on the same side (e.g., first end plate 150). Return bus bar 143 can be connected to one cell (e.g., second-end cell 139 in FIG. 2D) and one electric terminal (not shown in FIG. 2D). Return bus bar 143 extends over battery cells 130 without making any other electrical connections to battery cells 130 or other components of bus bars 140.

Referring to FIG. 2E, in some examples, one example of disjoined components 144 comprises two planar portions 145 and interconnecting rib 146, joining two planar portions 145. Two planar portions 145 are connected to cell terminals 134 of two adjacent battery cells 130. Interconnecting rib 146 can protrude from two planar portions 145 and in the direction away from battery cells 130, e.g., to provide in-plane movement flexibility between planar portions 145 (e.g., along the X-axis to accommodate the swelling of adjacent battery cells 130 corresponding to changing the distance between the attachment points between these cells and planar portions 145. It should be noted that interconnecting rib 146 protrudes into a fluidic channel and can (at least partially) block the fluidic path. As such, interconnecting rib 146 comprises one or fluid path openings 147 to assist with this flow. Furthermore, interconnecting rib 146 can assist with the mixing of thermal fluid 105 within the channel thereby enhancing the thermal transfer characteristics.

Referring to FIG. 2F, bus bars 140 in first bus-bar row 141 are connected to cell terminals 134 having one polarity (e.g., positive cell terminals), while bus bars 140 in second bus-bar row 142 are connected to cell terminals 134 having the other polarity (e.g., negative cell terminals). Further connections are provided through battery cells 130. Since cell terminals 134 are positioned on first surfaces 131, bus bars 140 are also positioned next to first surfaces 131.

It should be noted that during the operation of the swappable battery module 120, bus bars 140 are immersion-thermally controlled as further described below. As such, the cross-section of bus bars 140 can be reduced in comparison to bus bars that are not thermally controlled thereby allowing some resistive heating within bus bars 140. For example, the temperature coefficient of copper is about 0.00404 C⁻¹. Therefore, increasing the temperature of copper bus bars by 50° C. will cause the resistivity to increase by about 20%. Without the temperature control of bus bars 140, the dimensions of bus bars 140 need to accommodate the highest operating temperature. It should be noted that the heating of bus bars 140 can be caused by receiving the heat from battery cells 130 and from the internal resistive heating. However, increasing the size of bus bars 140 (to accommodate for higher operating temperatures) is highly undesirable since this increases the weight and size of bus bars 140 (and as a result of swappable battery module 120). Furthermore, bus bars 140 can be used (in addition to thermal fluid 105) for transferring the heat between battery cells 130.

Referring to FIG. 2G, tubular enclosure 170 is attached to each of the first surfaces 131, second surfaces 132, and side surfaces 133 of prismatic battery cells 130. Tubular enclosure 170 forms the first fluid channel 121 and second fluid channel 122 with a portion of the first surfaces 131. Similarly, tubular enclosure 170 forms third fluid channel 125 and fourth fluid channel 126 with a portion of second surfaces 132. These fluid channels are used for circulating thermal fluid 105 through swappable battery module 120 and, more specifically, for direct contact between thermal fluid 105 and prismatic battery cells 130 thereby establishing immersion thermal transfer between thermal fluid 105 and prismatic battery cells 130 (e.g., immersion cooling). In some examples, one or more fluid channels comprise channel inserts 123, e.g., as shown in the expanded view of the fourth fluid channel 126 at the bottom of FIG. 2G. For example, channel inserts 123 can provide support to the tubular enclosure 170 relative to the prismatic battery cells 130 as well as other components positioned within the channels (e.g., bus bars 140). Furthermore, channel inserts 123 can control the fluidic paths, flow rates, and other aspects associated with immersion cooling.

Overall, each prismatic battery cell 130 is immersed/comes in contact with the thermal fluid provided in all four fluid channels, i.e., first fluid channel 121, second fluid channel 122, third fluid channel 125, and fourth fluid channel 126. Each prismatic battery cell 130 is thermally controlled (e.g., immersion-cooled and/or immersion-heated) from the first surface 131 and second surface 132 thereby ensuring more a uniform temperature profile within prismatic battery cell 130 (e.g., in comparison to one-sided cooling of battery cells). Furthermore, the first fluid channel 121 and second fluid channel 122 are also used for cooling bus bars 140. For example, the first bus-bar row 141 protrudes into the first fluid channel 121 while the second bus-bar row 142 protrudes into the second fluid channel 122.

FIG. 2H illustrates one example of the fluidic flow paths within a swappable battery module 120. Specifically, the first end plate 150 comprises first fluidic port 251 and second fluidic port 252. Thermal fluid 105 can enter swappable battery module 120 through first fluidic port 251. First fluidic port 251 is fluidically coupled to both first fluid channel 121 and third fluid channel 125. Thereby, thermal fluid 105 is directed from first fluidic port 251 in both first fluid channel 121 and third fluid channel 125. When thermal fluid 105 flows through first fluid channel 121, thermal fluid 105 comes in contact with first surfaces 131 of battery cells 130 (or, more specifically, portions of these surfaces). Similarly, when thermal fluid 105 flows through third fluid channel 125, thermal fluid 105 comes in contact with second surfaces 131 of battery cells 130 (or, more specifically, portions of these surfaces). Once thermal fluid 105 reaches second end plate 160, a portion of thermal fluid 105 from first fluid channel 121 is redirected to second fluid channel 122, while the other portion of thermal fluid 105 from third fluid channel 125 is redirected to fourth fluid channel 126. As further described below, second end plate 160 fluidically interconnects first fluid channel 121 and third fluid channel 125. Second end plate 160 also fluidically interconnects second fluid channel 122 and fourth fluid channel 126 (independently from first fluid channel 121 and third fluid channel 125). Thermal fluid 105 then flows through second fluid channel 122 and again comes in contact with first surfaces 131 of battery cells 130 (now with different portions of these surfaces). Similarly, the other portion of thermal fluid 105 flows through fourth fluid channel 126 and comes in contact with second surfaces 131 of battery cells 130 (again with different portions of these surfaces). Second fluidic port 252 is fluidically coupled to both second fluid channel 122 and fourth fluid channel 126 and receives thermal fluid 105 from both of these channels, after which thermal fluid 105 is discharged from batter module 120 through second fluidic port 252.

Referring to FIG. 2I, as the thermal fluid having an inlet temperature (Tᵢₙ) enters swappable battery module 120, the thermal fluid receives the heat (H₁) and increases the fluid temperature as the fluid continues to flow through the module. For example, upon reaching the last cell in this series (second-end cell 139), the fluid temperature (Tₓ) will be higher that the inlet temperature (Tₓ>Tᵢₙ). Assuming that all battery cells have the same temperature (T_{cell}), the first cell (first-end cell 137) that comes in contact with the immediately incoming (colder) fluid will lose more heat than any subsequent cell in this series since the heat transfer is proportional to the temperature gradient between the cell and the fluid. For example, the heat transfer from the last cell in this series (Hₓ∝T_{cell}−Tₓ) will be smaller than the heat transfer from the first cell in this series (H₁∝T_{cell}−Tᵢₙ) due to the thermal fluid heating and the thermal gradient reduction (Tᵢₙ<Tₓ→H₁>Hₓ). If the thermal fluid is not looped and allowed to exit on the other side of the swappable battery module, then the first cell will be cooled more than the last cell. However, when the thermal fluid is looped and has both first fluid channel 121 and second fluid channel 122 (both providing fluidic contact to each cell), there is additional heat transfer occurs from each cell. Specifically, the heat transfer provided by first fluid channel 121 is described above resulting in the first cell will be cooled more than the last cell. However, as the thermal fluid is directed from first fluid channel 121 to second fluid channel 122, the order of the cell experiencing the flow is flipped while the thermal fluid continues to heat. The last cell sees this return flow first and experiences additional heat transfer (H′ₓ∝T_{cell}−T′ₓ). The first cell sees this return flow last and also experiences additional heat transfer (H′₁∝T_{cell}−Tₒᵤₜ). Since the thermal fluid continues to heat (Tₒᵤₜ>T′ₓ), the last cell is now cooled more (H′ₓ>H′₁). Combining the two heat transfers (provided by first fluid channel 121 to second fluid channel 122), the total heat transfer is more balanced (Hₓ+H′ₓ˜H₁+H′₁) than the heat transfer provided by each of the channels individually. While the above example is provided for cells' cooling, one having ordinary skill in the art would understand how the same concept applies to cells' heating.

Returning to FIG. 2G, first fluid channel 121 and third fluid channel 125 are formed by tubular enclosure 170 with a portion of first surfaces 131. Similarly, third fluid channel 125 and fourth fluid channel 126 are formed by tubular enclosure 170 with a portion of second surfaces 132. In this example, first bus-bar row 141 extends within first fluid channel 121. In other words, both first surfaces 131 of battery cells 130 and first bus-bar row 141 can be thermally controlled (e.g., cooled and/or heated) while thermal fluid 105 flows through third fluid channel 125. First bus-bar row 141 is connected to cell terminal 134. A portion of tubular enclosure 170 can be protected from contacting first bus-bar row 141 and cell terminal 134 by an insulator, thereby maintaining the electric neutrality of tubular enclosure 170. In this illustrated example, second bus-bar row 142 extends within second fluid channel 122. Furthermore, return bus bar 143 (if one is present) can extend through either first fluid channel 121 or second fluid channel 122. Return bus bar 143 may be operable as a return bus bar as described above.

Referring to FIG. 2G, in some examples, tubular enclosure 170 comprises first enclosure portion 171 and second enclosure portion 172, each independently attached to each of first surfaces 131, second surfaces 132, and side surfaces 133 of prismatic battery cells 130. Each of first enclosure portion 171 and second enclosure portion 172 is also independently attached to each of first end plate 150 and second end plate 160 (not shown in FIG. 2F). Each of first enclosure portion 171 and second enclosure portion 172 can be independent monolithic components (e.g., a shaped metal sheet). However, these portions are not monolithic with each other. Separating tubular enclosure 170 into first enclosure portion 171 and second enclosure portion 172 simplified the assembly of swappable battery module 120, e.g., positioning battery cells 130 with tubular enclosure 170. In some examples, each of first enclosure portion 171 and second enclosure portion 172 is glued to each of first surfaces 131, second surfaces 132, and side surfaces 133 of prismatic battery cells 130. Similarly, each of first enclosure portion 171 and second enclosure portion 172 can be glued to each of first end plate 150 and second end plate 160.

Referring to FIG. 2G, in some examples, tubular enclosure 170 further comprises interconnecting portion 173, attached to each of first enclosure portion 171 and second enclosure portion 172 and forming gas-ventilation channel 177 with first surfaces 131 of prismatic battery cells 130. Interconnecting portion 173 effectively interconnects (bridges) first enclosure portion 171 and second enclosure portion 172 while extending above first surfaces 131 of prismatic battery cells 130. In some examples, interconnecting portion 173 is glued to each of first enclosure portion 171 and second enclosure portion 172. As noted above, prismatic battery cells 130 comprise pressure-release burst valves 136 positioned on first surfaces 131. These pressure-release burst valves 136 are in fluid communication with gas-ventilation channel 177.

In case one or more prismatic battery cells 130 experience internal over-pressurization, the corresponding pressure-release burst valves 136 open and release internal gases (and possibly other matter) from these cells into gas-venting channel 177 thereby allowing to depressurize the cells. In some examples, gas-venting channel 177 is fluidically isolated from other components, e.g., bus bars 140, thereby preventing further propagation of unsafe conditions and even potentially continuing the operation of swappable battery module 120. In some examples, one or both of first end plate 150 and second end plate 160 comprise burst valves to vent gases from swappable battery module 120 (e.g., when the pressure inside gas-venting channel 177 exceeds a set threshold).

In some examples, swappable battery module 120 further comprises sensor wires 127, functionally coupled to each of prismatic battery cells 130 and protruding within gas-ventilation channel 177 to first end plate 150. For example, sensor wires 127 can be coupled to cell terminals 134 and/or bus bar portions (e.g., used for voltage sensing) and/or to thermocouples and/or other sensors disposed inside swappable battery module 120. Sensor wires 127 can extend to first end plate 150 for connecting to battery management system 128 and/or forming one or more external connections.

In some examples, swappable battery module 120 comprises handle 178, e.g., for carrying swappable battery module 120 between electric vehicle 100 and external charger 180 and/or for positioning the swappable battery module 120 on the electric vehicle 100 and external charger 180. Handle 178 is coupled (e.g., glued) to tubular enclosure 170 or, more specifically, interconnecting portion 173, e.g., as shown in FIG. 2G. In other examples, handle 178 is coupled (e.g., glued) to the side of tubular enclosure 170, which is opposite of interconnecting portion 173/gas-ventilation channel 177. More specifically, handle 178 is coupled to the side of tubular enclosure 170 adjacent to second surfaces 132 of battery cells 130. In these examples, when swappable battery module 120 is not fluidically coupled to either electric vehicle 100 or external charger 180, the residual thermal fluid 105 still occupies first fluid channel 121 and second fluid channel 122 thereby helping to maintain bus bars 140 inside this residual thermal fluid 105 (e.g., additional thermal mass and/or thermal conductivity to other pack components provided this by residual thermal fluid 105). It should be noted that the installation orientation (relative to the gravitational direction) of swappable battery module 120 on electric vehicle 100 and external charger 180 is such that handle 178 faces up while the residual thermal fluid 105 will be at the bottom of swappable battery module 120. It should also be noted that swappable battery module 120 can also be used under some operating conditions (e.g., low currents) without being fluidically coupled and without circulating thermal fluid 105 inside swappable battery module 120. In these examples, the residual thermal fluid 105 still assists with the heat dissipation with swappable battery module 120. In some examples, another handle can be attached to second end plate 160 and is used during the installation of swappable battery module 120 on electric vehicle 100 and external charger 180.

Referring to FIGS. 2J and 2K, in some examples, first end plate 150 comprises two electrical-terminal openings 153 (for installing first electrical terminal 241 and second electrical terminal 242—not shown in FIGS. 2J and 2K) and two fluid-port openings 154 (for installing first fluidic port 251 and second fluidic port 252—not shown in FIGS. 2J and 2K). Ins some examples, first fluidic port 251 and second fluidic port 252 are positioned further away from the side edges of first end plate 150 than corresponding first electrical terminal 241 and second electrical terminal 242. Alternatively, first fluidic port 251 and second fluidic port 252 are positioned closer to the side edges of first end plate 150 than the corresponding first electrical terminal 241 and second electrical terminal 242.

In some examples, the first end plate 150 comprises center protrusion 157 and two side edges 156. In swappable battery module 120 side edges 156 extend alongside surfaces 133 of first-end cell 137. Referring to FIG. 2K, two side edges 156 and center protrusion 157 from edge channels 158 fluidically coupling first fluid channel 121 and third fluid channel 125 and, separately, fluidically coupling second fluid channel 122 and fourth fluid channel 126.

Referring to FIG. 2J, in some examples, first end plate 150 comprises outer cavity 155 such that battery management system 128 is positioned with outer cavity 155 (e.g., as shown in FIG. 2B). First end plate 150 also comprises passthrough 159 such that sensor wires 127 protrude through passthrough 159 and are sealed within passthrough 159.

In some examples, first end plate 150 comprises side edges 156 extending between first-end-plate outer surface 151 and first-end-plate inner surface 152. At least a portion of these side edges 156 can extend into and can be attached (e.g., glued and sealed) to tubular enclosure 170. In some examples, fasteners are used for connecting first end plate 150 tubular enclosure 170. In some examples, first end plate 150 is also glued to first-end cell 137.

Referring to FIG. 2L, in some examples, second end plate 160 comprises first cavity 162 fluidically coupling first fluid channel 121 and second fluid channel 122. Second cavity 164 fluidically couples third fluid channel 125 and fourth fluid channel 126. In battery assembly, second end plate 160 is attached to tubular enclosure 170, fluidically interconnecting first fluid channel 121 and third fluid channel 125, and fluidically interconnecting second fluid channel 122 and fourth fluid channel 126. For example, a portion of second end plate 160 protrudes into and is glued to tubular enclosure 170. In some examples, second end plate 160 is also glued to second-end cell 139.

In some examples, each of first fluidic port 251 and second fluidic port 251 is configured to form fluidic coupling 300 with a corresponding fluidic port on one or both of electrical vehicle 100 and external charger 180. One example of fluidic coupling 300 is shown in FIGS. 3A and 3B. Specifically, fluidic coupling 300 comprises first component 301 and second component 302, configured to form a sealed fluidically coupling with each other in a coupled state (FIG. 3A) and to disconnect from each other while transitioning into a decoupled state (FIG. 3B). Either first component 301 or second component 302 can be operable as each of first fluidic port 251 and second fluidic port 251. When first component 301 is used as a fluidic port of swappable battery module, second component 302 is used to electric vehicle 100 and/or external charger 180. Alternatively, when second component 302 is used as a fluidic port of swappable battery module 120, first component 301 is used to electric vehicle 100 and/or external charger 180. It should be noted that second component 302 has a lower profile (no protrusions beyond its main body) thereby making second component 302 more suitable as a fluidic port of swappable battery module 120

Referring to FIGS. 3A and 3B as well as FIGS. 5G-5I, first component 301 comprises first body 310, first spool 320, first seal 315, slider 340, first slider seal 345, and first spring 350. First spool 320 is slidably coupled to first body 310 and also to slider 340. First spool 320 is also biased, relative to first body 310 and/or to slider 340, by first spring 350 (e.g., in the direction of second component 302). Second component 302 comprises second body 360, second seal 365, second spool 370, and second spring 380. Second spool 370 is slidably coupled to and biased, by second spring 380, relative to second body 360. Specifically, second spool 370 is biased in the direction of first component 301. For clarity (not to obstruct the fluidic paths in the presented cross-sectional views), FIGS. 5G-5I do not illustrate positive stops for first spool 320 or second spool 370.

When fluidic coupling 300 is in the coupled state, e.g., as shown in FIG. 3A, first spool 320 extends into second body 360 and is sealed against second body 360 by second seal 365. In another example shown in FIG. 5G, second body 360 protrudes into first body and is sealed against first seal 315. At the same time, first spool 320 is sufficient retracted into first body 310 allowing slider 340 to extend past first spool 320 and into second body 360 (e.g., as shown in both FIGS. 3A and 5G). Referring to the example in FIG. 3A, slider 340 comprises slider opening 375 which allows thermal fluid 105 to flow from between the cavity inside slider 340 and the space between slider 340 and second body 360. Thermal fluid 105 can also flow through second-spool opening 375 between this space and the cavity of second spool 370. In other words, in this state, a fluidic pathway is provided between the cavity inside slider 340 and the cavity of second spool 370 thereby allowing the flow of thermal fluid 105 through fluidic coupling 300. At the same time, first spool 320 remains sealed against first body 310 by first seal 315 and also against second body 360 by second seal 365 thereby sealing the interface between first body 310 and second body 360. Referring to the example in FIG. 5G, first spool 320 is pushed away from first slider seal 345. Furthermore, second body 360 is pushed past both second seal 365 and first slider seal 345. This displacement of first body 310 and second body 360 opens up a pathway between second body 360 and second spool 370 as well as between second body 360 and slider 340 thereby allowing thermal fluid 105 to flow between the cavity in second body 360 and the cavity in first body 310. First body 310 may also comprise one or more openings 311 (e.g., inlet or outlet openings) may be provided in first body 310 and radially oriented (e.g., relative to along primary axis 129) thereby directing thermal fluid 105 within first end plate 150 more efficiently. As a result, the thickness of first end plate 150 may be reduced (no additional axial to radial redistribution of thermal fluid 105 is needed). The flow of thermal fluid 105 in first end plate 150 is described above with reference to FIG. 2K.

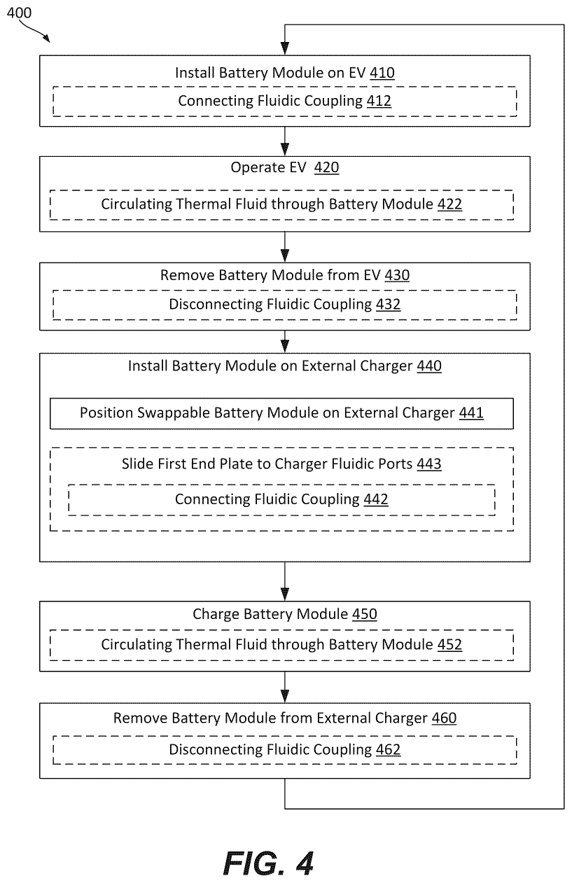

When fluidic coupling 300 is in the decoupled state, e.g., as shown in FIG. 3B and FIG. 5I, first spool 320 is sealed relative to slider 340 by first slider seal 345 thereby blocking the flow of thermal fluid 105 from first component 301. First spool 320 remains sealed against first body 310 by first seal 315. Furthermore, second spool 370 is sealed relative to second body 360 by second seal 365 thereby blocking the flow of thermal fluid 105 from second component 302. The transition between the coupled state and decoupled state is described below with reference to FIG. 4 and FIGS. 5A-5I below.

### Examples of Methods of Operating Swappable Battery Modules

FIG. 4 is a process flowchart corresponding to method 400 of operating swappable battery module 120, in accordance with some examples. Method 400 may commence with (block 410) installing swappable battery module 120 on electric vehicle 100. For example, electric vehicle 100 can include a bay for receiving swappable battery module 120. During this installation operation, swappable battery module 120 forms an electrical connection with electric vehicle 100 using first electrical terminal 241 and second electrical terminal 242. For example, electric vehicle 100 can include corresponding terminals configured to connect with the first electrical terminal 241 and second electrical terminal 242. In some examples, swappable battery module 120 forms a mechanical connection with electric vehicle 100 (e.g., locked using a latching mechanism). Furthermore, in some examples, installing swappable battery module 120 on electric vehicle 100 comprises (block 412) forming a fluidic coupling between swappable battery module 120 and electric vehicle 100, e.g., using first fluidic port 251 and second fluidic port 252 of swappable battery module 120. One example of such coupling is shown and described above with reference to FIGS. 3A and 3B. Additional features are described below with reference to FIGS. 5A-5F below. This fluidic coupling is optional, and, in some examples, swappable battery module 120 is not fluidically connected to electric vehicle 100.

Method 400 may proceed with (block 420) operating electric vehicle 100, e.g., by powering electric vehicle 100 from swappable battery module 120. As a result, swappable battery module 120 is discharged during this operation. It should be noted that, in some examples, swappable battery module 120 may be also charged onboard electric vehicle 100. In some examples (when swappable battery module 120 is fluidically connected to electric vehicle 100), operating electric vehicle 100 may comprise (block 422) circulating thermal fluid 105 through swappable battery module 120. For example, electric vehicle 100 may include vehicle thermal management system 110, which is designed to condition the temperature of thermal fluid 105 (e.g., by heating and/or cooling thermal fluid 105) and to pump thermal fluid 105 through swappable battery module 120. In some examples, swappable battery module 120 and electric vehicle 100 can be communicatively coupled during this operation. For example, swappable battery module 120 can measure the internal cell temperature and send this information to vehicle thermal management system 110.

Method 400 may proceed with (block 430) removing battery module 120 from electric vehicle 100. This operation may be the reverse of the installation operation (block 410) described above. During the module removal operation, the electrical connection between swappable battery module 120 and electric vehicle 100 is separated (e.g., by disconnecting first electrical terminal 241 and second electrical terminal 242 from the corresponding terminals on electric vehicle 100). In some examples (when swappable battery module 120 is fluidically connected to electric vehicle 100), the battery removal operation (block 430) also comprises (block 432) disconnecting the fluidic coupling between swappable battery module 120 and electric vehicle 100 as will now be described with reference to FIGS. 5A-5F.

Specifically, FIG. 5A illustrates fluidic coupling 300 is in the coupled state, which is described above with reference to FIG. 3A. FIG. 5B illustrates the first step in this disconnecting operation where first body 310 is moved away from second body 360. First spool 320 is biased by first spring 350, which pushes first spool 320 out of first body 310. At this step, the second body 360 is operable as a positive stop for first spool 320. In fact, the second body 360 is operable as a positive stop for first spool 320 during the coupled state in FIG. 5A and the next/second step in FIG. 5C. Referring to FIG. 5B, slider 340 follows first body 310 and is retracted into first spool 320. At this step, first slider seal 345 is not contacting/sealed against first spool 320 thereby allowing thermal fluid 105 to flow (through second-spool opening 375) between the cavity inside slider 340 and the space between slider 340 and second body 360. At the same time, as slider 340 follows first body 310 and is retracted into first spool 320, second spool 370 is biased toward first spool 320. FIG. 5B illustrates a point where second spool 370 reaches and contacts first spool 320. From this point on, first spool 320 is operable as a positive stop for second spool 370, at least through the few steps described below. In the coupled state of FIG. 5A, slider 340 acted as a positive stop for second spool 370. This spool contact can restrict the flow of thermal fluid 105 (in comparison to the coupled state of FIG. 5A) but does not fully seal the flow.

FIG. 5C illustrates the second step in this disconnecting operation where first body 310 is moved further away from second body 360 (in comparison to the first step of FIG. 5B). Slider 340 follows first body 310 and is retracted into first spool 320. However, at this step, first slider seal 345 is sealed against first spool 320 thereby preventing thermal fluid 105 to flow between the cavity inside slider 340 and the space between slider 340 and second body 360. First spool 320 continues being pushed out of first body 310 by first spring 350 with second body 360 still operable as a positive stop.

FIG. 5D illustrates the third step in this disconnecting operation where first body 310 is moved further away from second body 360 (in comparison to the second step of FIG. 5C). First slider seal 345 remains sealed against first spool 320 thereby preventing the flow of thermal fluid 105. First spool 320 is no longer being pushed out of first body 310 since a feature of first body 310 is now operable as a positive stop for first spool 320. As such, first spool 320 is now being extracted from second body 360. However, second seal 365 still seals against first spool 320 at this stage.

FIG. 5E illustrates the fourth step in this disconnecting operation where first body 310 is moved further away from second body 360 (in comparison to the second step of FIG. 5D). First slider seal 345 remains sealed against first spool 320 thereby preventing the flow of thermal fluid 105. First spool 320 continues being extracted from second body 360. The specific point (shown in FIG. 5E) can be referred to as the “second seal handoff” where second seal 365 disengages first spool 320 and engages second spool 370, which follows the travel of first spool 320.

Finally, FIG. 5F illustrates the decoupled state where first body 310 is moved even further away from second body 360 (in comparison to the second step of FIG. 5E). This decoupled state is described above with reference to FIG. 3B.

FIGS. 5G-5I are schematic cross-sectional side views of additional examples of a fluidic coupling at different stages while decoupling the first component 301 from the second component 302. FIG. 5G illustrates fluidic coupling 300 is in the coupled state, which is described above. FIG. 5H illustrates an intermediate step in this disconnecting operation where second body 360 is moved away from first body 310 (or first body 310 is moved away from second body 360). First spool 320 is biased by first spring 350, which pushes first spool 320 to the gap between first body 310 and slider 340 and causes first spool 320 to seal against first seal 315 and first slider seal 345 thereby sealing the first component 301 (i.e., thermal fluid 105 can not transfer between slider 340 and first spool 320). As noted above, positive stops for first spool 320 and second spool 370 are not shown in FIGS. 5G-5I to avoid visual obstruction of fluidic pathways. Furthermore, first spring 350 and second spring 380 are schematically illustrated as dashed lines. As noted above, at this step, the second body 360 is operable as a positive stop for first spool 320. In fact, the second body 360 is operable as a positive stop for first spool 320 during the coupled state in FIG. 5G.

Slider 340 may remain stationary (relative to first body 310 during disconnecting and reconnecting operations). In both FIGS. 5G and 5H, slider 340 acts as a positive stop for second spool 370, determining the position of second spool 370 relative to first body 310. It should be noted that second body 360 may move relative to first body 310 while second spool 370 may remain stationary relative to first body 310. As such, retracting first body 310 from second body 360 (as shown in FIGS. 5G and 5H) moves second spool 370 relative to second body 360, e.g., until second seal 365 is sealed against second body 360. At this point, second component 302 is sealed. Finally, FIG. 5I illustrates the decoupled state where first body 310 is moved even further away from second body 360 (in comparison to the step of FIG. 5H). This decoupled state is described above.

The cross-sectional views of FIGS. 5G-5I focuses on fluidic pathways within fluidic coupling 300 without focusing radial support to various movable components such as first spool 320 and second spool 370. Some aspects of this radial support are shown in FIGS. 5G-5I with dotted lines and will now be further described with reference to FIGS. 5J and 5K. Specifically, FIG. 5J is a schematic perspective view of the first spool 320 comprising a leading portion 321 and a tail portion 322. The outside surface of the leading portion 321 may have a cylindrical shape for sealing against the first seal 315 when fluidic coupling 300 is decoupled (e.g., as shown in FIGS. 5H and 5I). The diameter of this cylindrical shape ensures the sealable coupling with the first seal 315.

The tail portion 322 comprises a first-spool cylindrical portion 323 and one or more first-spool fluidic pathways 324. The first-spool cylindrical portion 323 also has a cylindrical shape enabling slidable coupling between the first spool 320 and first body 310. The one or more first-spool fluidic pathways 324 are recessed away from this cylindrical shape and provide one or more passages for fluid between the first spool 320 and first body 310, e.g., when the first spool 320 is advanced into a decoupled positioned (e.g., as shown in FIGS. 5H and 5I). Specifically, as the leading portion 321 is being sealed against the first seal 315 a portion of the fluid may be trapped between the first body 310 and the interface of the leading portion 321 and tail portion 322. One or more first-spool fluidic pathways 324 allow for this trapped fluid to be displaced back into the interior of the first component 301 without being spilled. Any number of first-spool fluidic pathways 324 are within the scope, e.g., one, two, three, four (shown in FIG. 5J) or more. Also, any design of first-spool fluidic pathways 324 is within the scope, e.g., flat surfaces (shown in FIG. 5J), grooves, and the like.

FIG. 5K is a schematic perspective view of second spool 370 comprising a second-spool cylindrical portion 373 and one or more second-spool fluidic pathways 374. The second-spool cylindrical portion 373 has a cylindrical shape enabling slidable coupling between the second spool 370 and second body 360. The one or more second-spool fluidic pathways 374 are recessed away from this cylindrical shape and provide one or more passages for fluid between the second spool 370 and second body 360. Any number of second-spool fluidic pathways 374 are within the scope, e.g., one, two, three, four (shown in FIG. 5K) or more. Also, any design of second-spool fluidic pathways 374 is within the scope, e.g., flat surfaces, grooves (shown in FIG. 5K), and the like. Furthermore, FIG. 5K illustrates a recess 377 for positing and supporting the second seal 365,

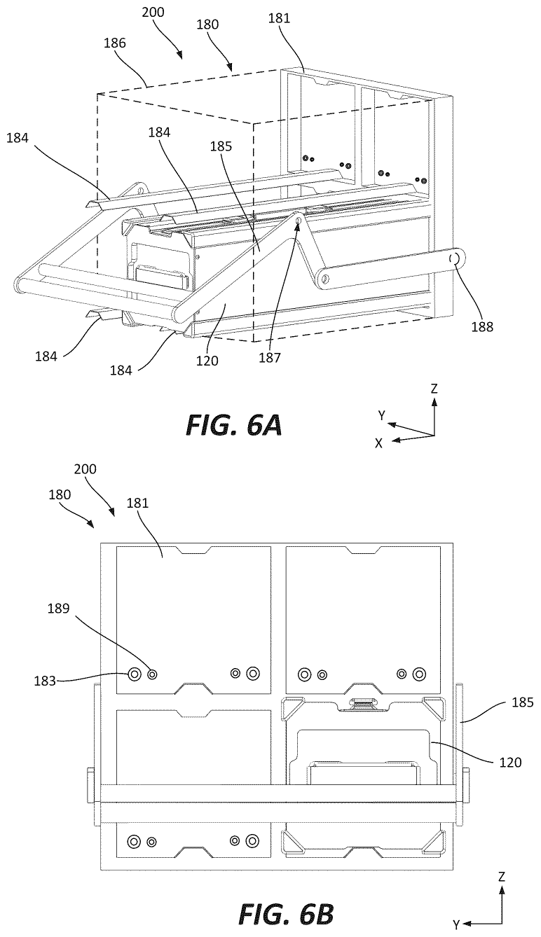

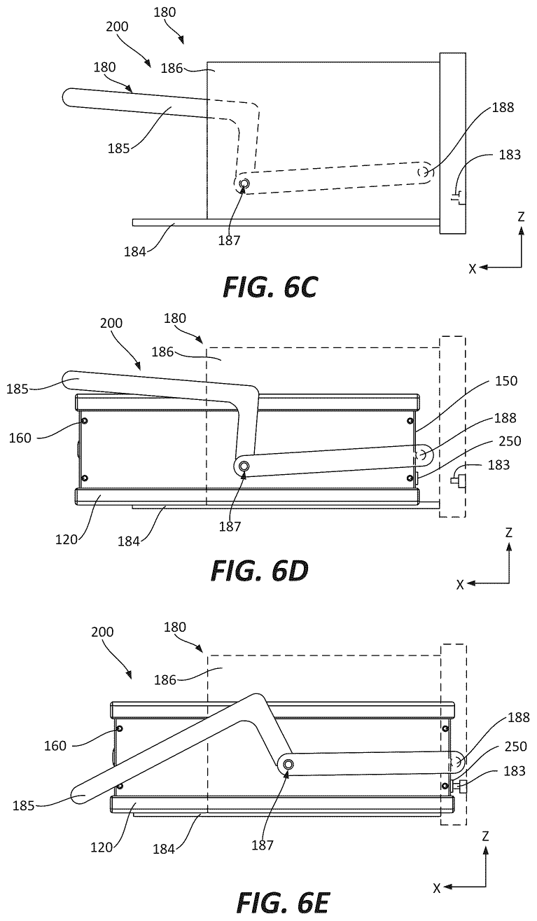

Returning to FIG. 4, method 400 may proceed with (block 440) installing swappable battery module 120 on the external charger 180 or, more generally, on the battery dock 200, which may be a part of either the external charger 180 or the electric vehicle 100. While the reference will be made to the external charger 180, one having ordinary skill in the art would understand that the same or similar operations may be performed while installing swappable battery module 120 on the electric vehicle 100. Furthermore, various components of the external charger 180 may be parts of the battery dock 200 (of this external charger or of the electric vehicle 100). For example, this installation operation may comprise (block 441) positioning swappable battery module 120 on charger 180 comprising dock fluidic ports 183. One example of charger 180/battery dock 200 is shown in FIGS. 6A-6E. It should be noted that a module connection on electric vehicle 100 may be configured in a similar manner and include the same components.

FIGS. 6A and 6B illustrate charger 180/battery dock 200 suitable for connecting to four swappable battery modules 120. However, only one swappable battery module 120 is shown in these views. Charger 180/battery dock 200 comprises dock base 181, providing four module bays (one for each swappable battery module 120). Each module bay comprises module support rail 184, two dock fluid ports 183, and two dock electric terminals 189. Module support rail 184 is configured to support swappable battery module 120 and allow swappable battery module 120 to slide in and out of the module bay while forming electric and fluid connections with charger 180/battery dock 200. Two dock fluid ports 183 are aligned (e.g., concentrically aligned) with corresponding fluid ports 250 of swappable battery module 120 while swappable battery module 120 is positioned on module support rail 184.

Each module bay also comprises limiting arm 185 pivotably coupled (at pivot point 187) to dock enclosure 186. Limiting arm 185 comprises limiting bar 188 positioned on the arm end proximate to dock base 181. Pivoting the limiting arm 185 changes the distance between limiting bar 188 and dock base 181 as will now be described with reference to reference to FIGS. 6C-6E.

Method 400 may proceed with (block 443) sliding first end plate 150 of swappable battery module 120 toward dock fluidic ports 183 until dock fluidic ports 183 are fluidically coupled with first fluidic port 251 and second fluidic port 252. In other words, this sliding operation also comprises (block 442) connecting the fluidic coupling or, more specifically, connecting fluidic ports 250 of swappable battery module with dock fluidic ports 183.

FIG. 6C is a schematic side view of charger 180/battery dock 200 without swappable battery module 120, in which limiting arm 185/limiting bar 188 is in the first position (further away from dock base 181). As swappable battery module 120 slides on support rail 184 toward dock base 181, swappable battery module 120 first contacts limiting bar 188 (e.g., as shown in FIG. 6D) that prevents swappable battery module 120 from hitting dock base 181 and, more specifically, prevents corresponding fluid ports 250 of swappable battery module 120 from hitting dock fluid ports 183 and, also, corresponding electric terminals 240 of swappable battery module 120 from hitting dock electric terminals 189. It should be noted that swappable battery module 120 is quite heavy and can carry significant momentum while sliding on support rail 184. It should be also noted that limiting bar 188 is positioned such that neither fluid ports 250 nor electric terminals 240 contact limiting bar 188 during this stage.

FIG. 6E is a schematic side view of charger 180/battery dock 200 with limiting arm 185/limiting bar 188 being in the position (closer to dock base 181). As limiting bar 188 transitions from the first position (in FIG. 6D) to the second position (in FIG. 6E), swappable battery module 120 is allowed to get closer to dock base 181 and form the electric and fluidic coupling with charger 180/battery dock 200.

Method 400 may proceed with (block 450) charging swappable battery module 120 on charger 180/battery dock 200. As a result, swappable battery module 120 is charged during this operation. In some examples (when swappable battery module 120 is fluidically connected to charger 180/battery dock 200), this charging operation may comprise (block 452) circulating thermal fluid 105 through swappable battery module 120. For example, charger 180 may include charger thermal management system 190, which is designed to condition the temperature of thermal fluid 105 (e.g., by heating and/or cooling thermal fluid 105) and to pump thermal fluid 105 through swappable battery module 120. In some examples, swappable battery module 120 and charger 180/battery dock 200 can be communicatively coupled during this operation. For example, swappable battery module 120 can measure the internal cell temperature and send this information to charger thermal management system 190.

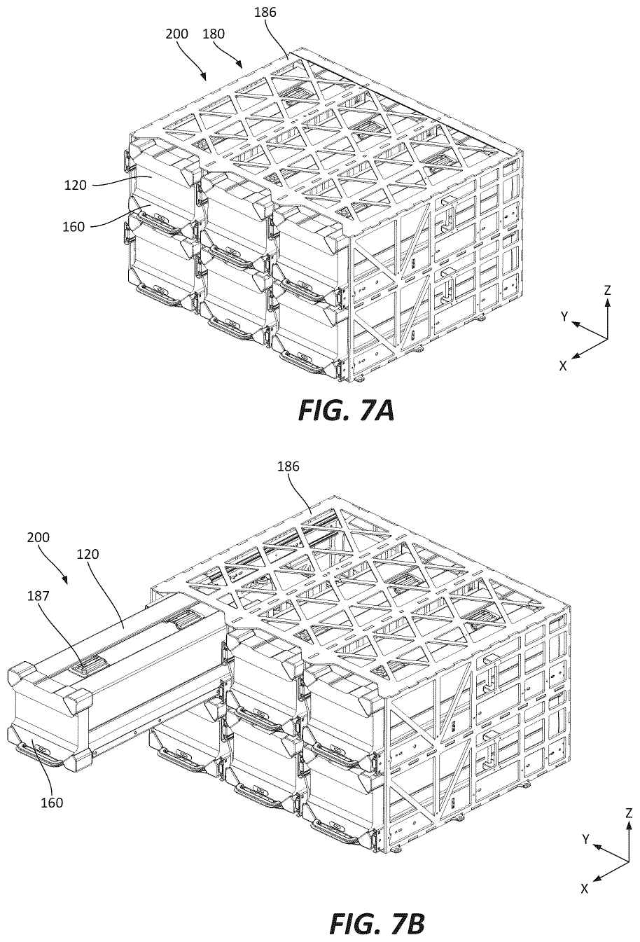

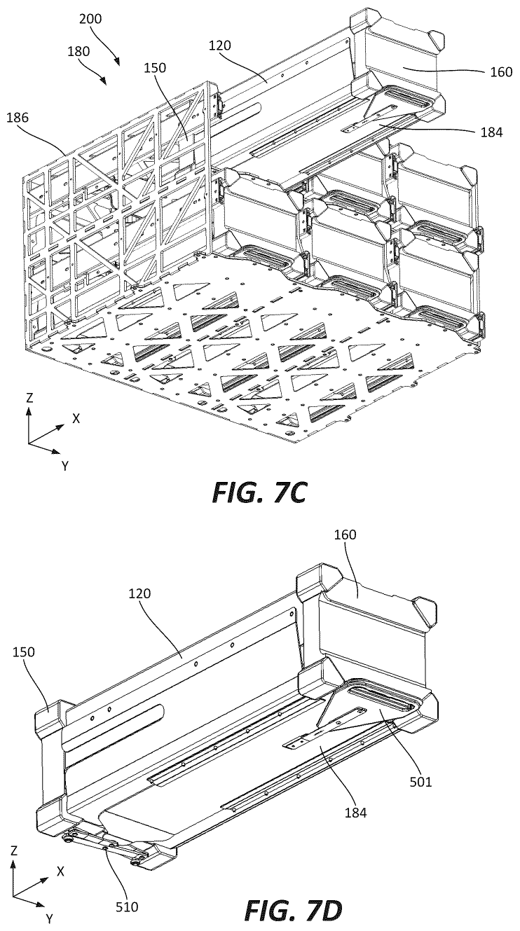

FIGS. 7A-7C illustrate another example of the charger 180/battery dock 200 with six swappable battery modules 120 positioned in this charger 180/battery dock 200, e.g., one in each module slot. The charger 180/battery dock 200 example (shown in FIGS. 7A and 7B) includes six module slots integrated into the same enclosure 186, while the example in FIGS. 6A and 6B includes four module slots. The number of module slots determines the maximum number of swappable battery module 120 that can be charged in the charger 180/battery dock 200 at the same time. It should be noted that fewer than the maximum number of swappable battery module 120 can be used in the charger 180 battery dock 200 at the same time. It should be also noted that a structure similar to the charger 180 maybe used on an electric vehicle 100, e.g., to discharge one or more swappable battery modules 120 during the operation of the electric vehicle 100 in the form of a battery dock 200.

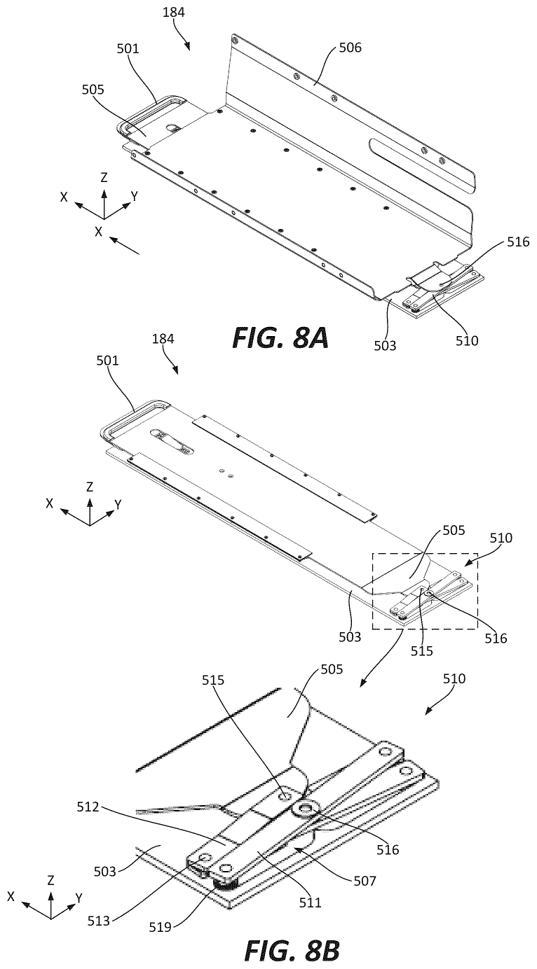

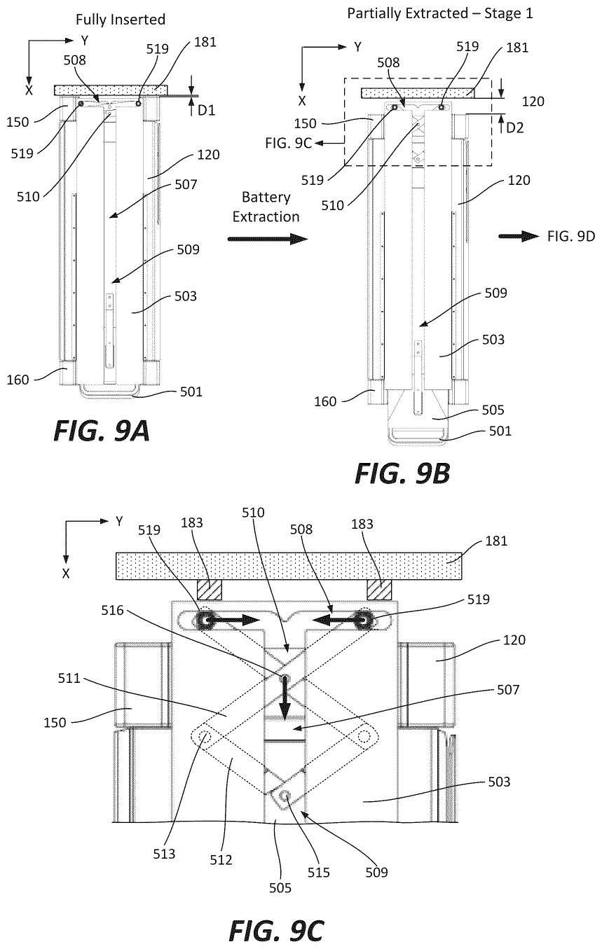

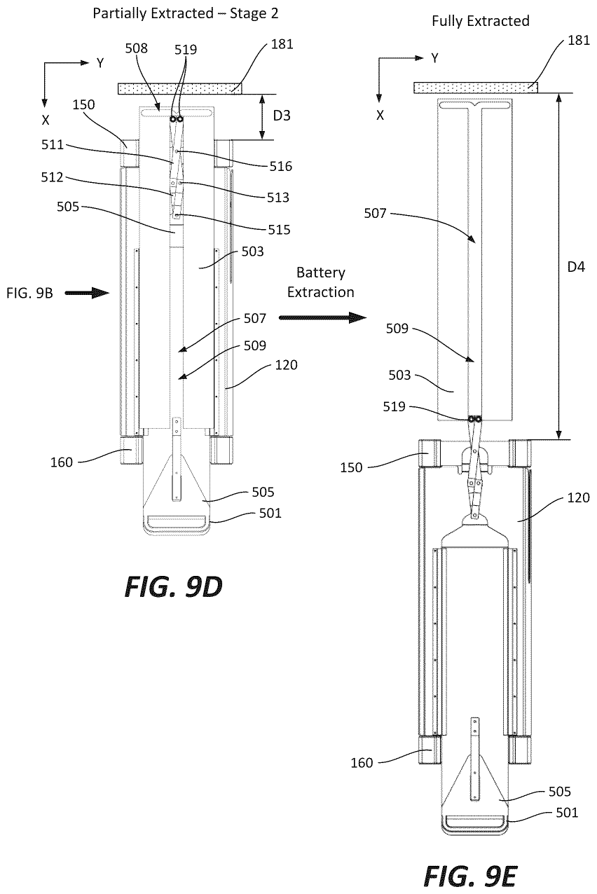

Similar to the example in FIGS. 6A and 6B, the charger 180/battery dock 200 in FIGS. 7A-7C comprises a module support rail 184 for supporting each swappable battery module 120, e.g., as shown in FIGS. 7C and 7D. However, the design of this module support rail 184 is different. Specifically, the design in FIGS. 7C and 7D allows the rail handle 501 to move at a higher speed than the swappable battery module 120, relative to the dock base 181 (from which the swappable battery module 120 is disconnected), during the initial removal stage of the swappable battery module 120 (e.g., while the dock fluidic ports 183 and two dock electric terminals 189 of the dock base 181 are being disconnected from the corresponding fluid ports 250 and corresponding electric terminals 240 on the swappable battery module 120). This speed difference is enabled by a lever-based unit 510 that controls the relative speed of the rail handle 501 and the swappable battery module 120. The speed difference allows for the use of a smaller force on the rail handle 501 than actually needed to disconnect these ports and terminals thereby reducing the strain on the operators. Furthermore, during the installation of the swappable battery module 120 to the charger 180/battery dock 200 or, more specifically, while the swappable battery module 120 is being inserted into a corresponding slot of the charger 180/battery dock 200, this speed difference helps to slowdown the swappable battery module 120 as the charger 180/battery dock 200 approaches the dock fluidic ports 183 and two dock electric terminals 189 of the dock base 181 thereby eliminating the significant impact in these ports and terminals. It should be noted that the swappable battery module 120 is relatively heavy. Various design features providing this speed/force difference will now be described with reference to FIGS. 8A, 8B, and 9A-9E.

Referring to FIGS. 8A and 8B, the module support rail 184 comprises a rail base 503, a first slider 505, a second slider 506, and a lever-based unit 510. The rail base 503 is fixedly attached to enclosure 186 and does not move during the removal/installation of the swappable battery module 120. The first slider 505 comprises a rail handle 501 positioned on the end of the first slider 505 opposite the end attached to the lever-based unit 510. When an operator pulls the rail handle 501, the lever-based unit 510 is actuated as further described below. The second slider 506 is configured to house a swappable battery module 120 (the swappable battery module 120 is not shown in FIG. 8A) For example, the second slider 506 may include a quick disconnect for supporting the swappable battery module 120 relative to the second slider 506.

The lever-based unit 510 independently connects each of the first slider 505 and the second slider 506 to the rail base 503. However, the connection points are different, which provides the speed difference as will now be described with reference to FIG. 8B. Specifically, the lever-based unit 510 comprises two sets of levers, i.e., the first lever set 511 and the second lever set 512. The first end of the first lever set 511 is connected to bushings 519 that protrude into a rail-base slot 507 of the rail base 503. The mid-point of the first lever set 511 is used as a second-slider connection point 516. The second end of the first lever set 511 is pivotably coupled (at a pivot point 513) to the first end of the second lever set 512. Finally, the second end of the second lever set 512 is used as a first-slider connection point 515. Since the first-slider connection point 515 and the second-slider connection point 516 are positioned on the different lever sets, the speed with which these points move along the X-axis during at least the initial stages of the removal of the swappable battery module 120 is different as further described below with reference to FIGS. 9A-9E.

Overall, the first lever set 511 is connected to the bushings 519 at a first end, pivotably connected to the first slider 505 at a midpoint, and pivotably connected to the second lever set 512 at a second end of the first lever set 511, opposite to the first end. The second lever set 512 is pivotably connected to the first lever set 511 and the first slider 505 at opposite ends of the second lever set 512. When the bushings 519 slides within in the engagement slot section 508, an angle between the first lever set 511 and the second lever set 512 changes. When the bushings 519 slides within the extraction slot section 509, the angle between the first lever set 511 and the second lever set 512 is constant.

In some examples, when the bushings 519 is in the engagement slot section 508, the first slider 505 moves at least twice faster or even at least three times faster than the second slider 506. The speed difference depends on the geometry of the lever-based unit 510, e.g., lengths of different portions of the first lever set 511 and second lever set 512.

Overall, the charger 180/battery dock 200 comprises an enclosure 186 and a module support rail 184 slidably coupling the swappable battery module 120 and the enclosure 186. The module support rail 184 comprises a rail base 503, a first slider 505, a second slider 506, and a lever-based unit 510, interconnecting the rail base 503, the first slider 505, and the second slider 506. The rail base 503 is fixed to the enclosure 186. The second slider 506 is detachably coupled to the swappable battery module 120. The first slider 505 and the second slider 506 move at different speeds or at a same speed relative to the dock base 181 depending on proximity of the first end plate 150 to the dock base 181.

In some examples, the rail base 503 comprises a rail-base slot 507 defined by an engagement slot section 508 and an extraction slot section 509, extending perpendicular to the engagement slot section 508. The lever-based unit 510 comprises bushings 519 slidably fit into the rail-base slot 507. When the bushings 519 is in the engagement slot section 508, the first slider 505 moves faster than the second slider 506 (and the lever-based unit 510 is unlocked and can expand and contract). When the bushings 519 is in the extraction slot section 509, the first slider 505 and the second slider 506 move at the same speed (and the lever-based unit 510 is locked).

Referring to FIGS. 9A-9E, the rail-base slot 507 comprises two sections, i.e., an engagement slot section 508 and an extraction slot section 509, extending perpendicular to the engagement slot section 508. When the swappable battery module 120 is connected to or even proximate to the dock base 181, the bushings 519 of the lever-based unit 510 slide within the engagement slot section 508. Specifically, the two bushings 519 are either brought close to each other (when the swappable battery module 120 is moved away from the dock base 181) or pushed away from each other (when the swappable battery module 120 is brought closer to the dock base 181). In fact, the opposite ends of the engagement slot section 508 define the stop point of the swappable battery module 120 when the swappable battery module 120 is slid towards the dock base 181. In other words, the engagement slot section 508 comprises end points, operable as positive stops and define a closest position between the swappable battery module 120 and the dock base 181.

It should be noted that because of the “scissor-like” design of the lever-based unit 510 (with pivot points 513), both the second-slider connection point 516 and the first-slider connection point 515 are able to move along the extraction slot section 509 (along the X axis) while the bushings 519 are still within the extraction slot section 509, e.g., as schematically shown in FIGS. 9A-9C. However, the linear speed (along the extraction slot section 509/the X axis) is different for different points. In the example, where the distance between the first-slider connection point 515 and the pivot point 513 is the same as the distance between the pivot point 513 and the second-slider connection point 516 and also the same as the distance between the second-slider connection point 516 and the bushings 519, the linear speed (along the extraction slot section 509/the X axis) of the first-slider connection point 515 is three times greater than the linear speed of the second-slider connection point 516. It should be noted that the linear speed (along the extraction slot section 509/the X axis) of the bushings 519 is zero, at least until the two bushings 519 reach the extraction slot section 509. As such, the speed of the first slider 505 (attached to the first-slider connection point 515) and the rail handle 501 (which is a part of the first slider 505) is three times greater than that of the second slider 506 (attached to the second-slider connection point 516) and the swappable battery module 120 (supported on the second slider 506). As such, the force that needs to be applied to the rail handle 501 is three times less than the force needed to accelerate/decelerate the swappable battery module 120 and disengage/engage various fluidic and electric connections.

Referring to FIGS. 9D and 9E, once the bushings 519 reaches the extraction slot section 509 and starts moving within the extraction slot section 509 (along the X-axis), the first lever set 511 and second lever set 512 can no longer pivot, and all three points (i.e., the bushings 519, the second-slider connection point 516, and the first-slider connection point 515 moves with the same linear speed (along the extraction slot section 509/the X axis). As such, the speed of the first slider 505 (attached to the first-slider connection point 515) and the rail handle 501 (which is a part of the first slider 505) is the same as the speed of the second slider 506 (attached to the second-slider connection point 516) and the swappable battery module 120 (supported on the second slider 506). This speed equality ensures faster removal of the swappable battery module 120 from the corresponding slot in enclosure 186. At this point, various fluidic and electric connections are already fully disengaged, and no additional force is needed. FIG. 9E illustrates a position with the swappable battery module 120 fully extended from the rail base 503, which can be associated with a slot in enclosure 186. In some examples, the bushings 519 are configured to slide out of the extraction slot section 509 thereby separating the rail base 503 from the first slider 505 and from the second slider 506 for complete removal of the swappable battery module 120 from the charger 180/battery dock 200.

Method 400 may proceed with (block 460) removing the swappable battery module 120 from charger 180/battery dock 200. This operation may be the reverse of the installation operation (block 440) described above. During the module removal operation, the electrical connection between swappable battery module 120 and charger 180/battery dock 200 is separated (e.g., by disconnecting first electrical terminal 241 and second electrical terminal 242 from the corresponding terminals on electric vehicle 100). In some examples (when swappable battery module 120 is fluidically connected to charger 180/battery dock 200), the battery removal operation (block 460) also comprises (block 462) disconnecting the fluidic coupling between swappable battery module 120 and charger 180/battery dock 200 in a manner similar to the one described above with reference to FIGS. 5A-5F.

### Examples of Out-of-Plane Bushing Supports

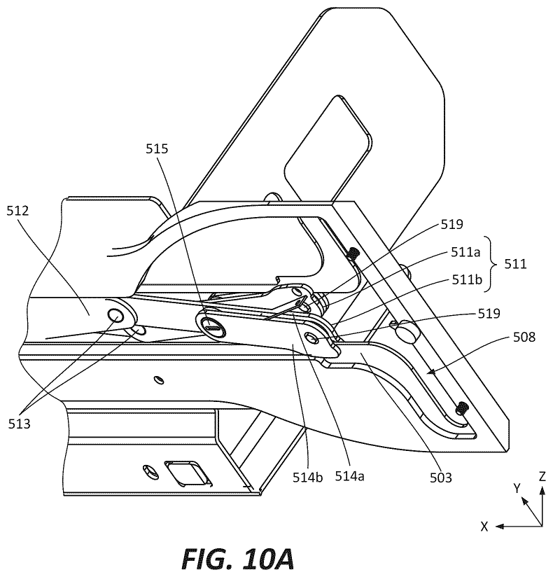

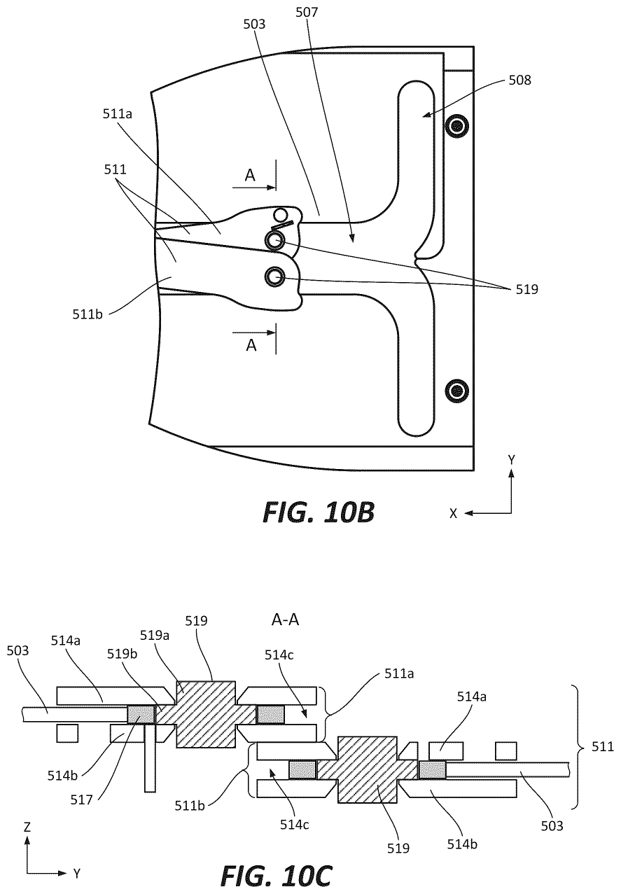

Referring to FIGS. 10A-10C, in some examples, the first lever set 511 is designed such that the bushings 519 are supported by the first lever set 511 from moving out of plane (i.e., along the Z-axis). The plane is defined by the rail base 503 (i.e., the X-Y plane). As noted above, the bushings 519 are movable with the X-Y plane while advancing within the rail-base slot 507, e.g., along the Y axis, when the bushings 519 are positioned within the engagement slot section 508 and also along the X-axis when the bushings 519 moved into the extraction slot section 509). However, if the bushings 519 are allowed to move out of the plane, then the bushings 519 can come out of the rail-base slot 507.

Specifically, FIGS. 10A-10C illustrates a cross-sectional view of a first lever set 511 supporting two bushings 519 relative to rail base 503. The first lever set 511 comprises a first lever 511a and a second lever 511b, each supporting one of the two bushings 519 and pivotably connected to each other at a first-slider connection point 515 (e.g., shown in FIG. 10A). Furthermore, each of the first lever 511a and second lever 511b is connected to a corresponding lever of the second lever set 512 at a pivot point 513 (e.g., as also shown in FIG. 10A).

To restrict the out-of-plane movement of the bushings 519, each of the first lever 511a and second lever 511b comprises a first lever unit 514a and a second lever unit 514b, offset relative to each other along the Z-axis and forming a gap 514c in between the two lever units, e.g., as shown in FIG. 10C. The gap 514c is maintained by a band 517, which can surround the corresponding bushing 519. The gap 514c may also allow the bushing 519 to rotate. For example, as shown in FIG. 10C, each bushing 519 may comprise a stem 519a protruding into the round openings of the first lever 511a and second lever 511b thereby forming a rotatable coupling. Furthermore, each bushing 519 may comprise a collar 519b that has a larger diameter than the stem 519a and that extends into the gap 514c between the first lever unit 514a and the second lever unit 514b. As such, the collar 519b maintains the axial position of the bushing 519 from between the first lever unit 514a and the second lever unit 514b, e.g., preventing it from sliding through the round openings of the first lever 511a and second lever 511b. At the same time, each bushing 519 is rotatably supported by either the first lever 511a and the second lever 511b thereby allowing the bushings 519 to rotate relative to the first lever set 511 when the bushings 519 are advanced in the rail-base slot 507. Alternatively, the bushings 519 or, more specifically, the collar 519b may be compressed the first lever unit 514a and the second lever unit 514b such that the rotation is limited due to the friction between the collar 519b and each of the first lever unit 514a and the second lever unit 514b. In this example, the collar 519b is operable as a spacer, while the band 517 surrounding each collar 519b may rotate about the collar 519b. For example, as shown in FIG. 10C is positioned between the rail base 503 and the bushing 519 and may come in contact with the rail base 503 when the bushing 519 and the band 517 advance through the rail-base slot 507. In other words, band 517 may rotate about the bushing 519 and roll over the edge of the rail-base slot 507 during this operation.

The rail base 503 also partially extends into the gap 514c of each of the first lever 511a and second lever 511b thereby supporting these levers along the Z axis. The rail base 503 may be maintained with the gap 514c and may contact with the bushings 519 or the bands 517 (if one is present). In some examples, a spring may be used within the first lever set 511 (or any other lever set) to bias the bushings 519 away from each other and maintain the edges of the rail base 503 within the corresponding gaps 514c. As such, a combination of the rail base 503 and the collar 519b protruding into the gap 514c provides in-plane support to the bushings 519 relative to the rail base 503 while allowing the bushings 519 to move with the rail-base slot 507.

### Examples of Interlocking Mechanisms

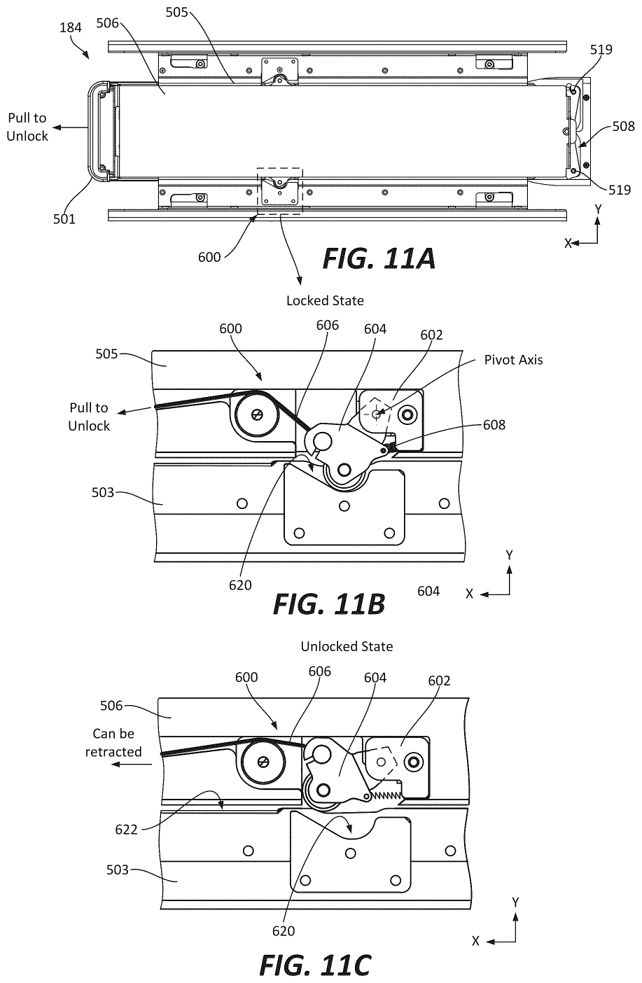

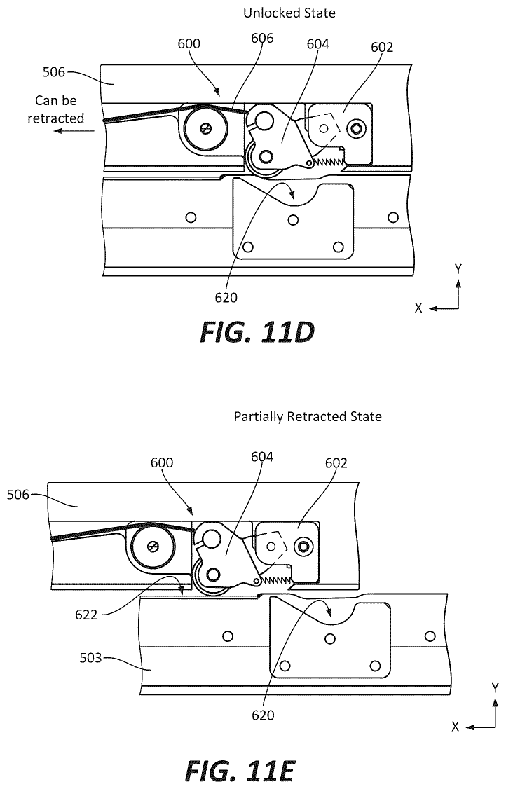

Once the swappable battery module 120 is connected to the charger 180/battery dock 200, the swappable battery module 120 needs to maintain its position relative to the charger 180/battery dock 200, which can be achieved by maintaining the module support rail 184 in the retracted position as shown in FIGS. 8A, 8B, 9A, and 11A. It should be noted that the module support rail 184 is designed to prevent furthermore movement of the swappable battery module 120 toward the charger 180/battery dock 200 with the bushings 519 reaching the ends of the engagement slot section 508. However, the bushings 519 and the engagement slot section 508 do not prevent the swappable battery module 120 from disconnecting and moving away from toward the charger 180/battery dock 200. For example, the bushings 519 can move towards each other within the engagement slot section 508 thereby causing the swappable battery module 120 to extend from the charger 180/battery dock 200. In some examples, to maintain the module support rail 184 in the retracted position, the module support rail 184 comprises a locking mechanism 600 as shown in FIG. 11A. Specific aspects of the locking mechanism 600 will now be described in the context of FIGS. 11B-11E.

Referring to FIGS. 11B, in some examples, the locking mechanism 600 is attached to the first slider 505 and interlocks with the rail base 503 (however, an inverse configuration is also within the scope). The locking mechanism 600 comprises a lock support 602, a pivotable lock 604 supported by the lock support 602, and an actuator 606 configured to pivot the pivotable lock 604 between a locked state (shown in FIG. 11B) and an unlocked state (shown in FIG. 11C). Furthermore, the locking mechanism 600 may comprise a spring 608 that biases the pivotable lock 604 to the locked state when the actuator 606 is not engaged (e.g., when a cable that is operable as an actuator 606 is not pulled). In the locked state, the pivotable lock 604 extends into a locking cavity 620 positioned on the rail base 503 such that the locking cavity 620 prevents the pivotable lock 604 from moving along the X-axis, e.g., as shown in FIG. 11B.

In some examples, the actuator 606 is a cable connected to the rail handle 501. When the rail handle 501 is pulled, the cable/actuator 606 pulls the pivotable lock 604 into the unlocked state (shown in FIG. 11C). In this unlocked state, the pivotable lock 604 no longer extends into the locking cavity 620 thereby allowing the first slider 505 to slide relative to the rail base 503, e.g., as shown in FIG. 11D. It should be noted that once the pivotable lock 604 is removed from the locking cavity 620 and slid along the X-axis away from the locking cavity 620, the pivotable lock 604 may engage/contact a rail edge 622 of the rail base 503 and slide relative to/roll on this rail edge 622, e.g., as shown in FIG. 11E. This feature allows the cable/actuator 606 to be released. When the pivotable lock 604 is aligned with the locking cavity 620 (and when the cable/actuator 606 is not engaged), the spring 608 pulls the pivotable lock 604 into the locking cavity 620 (corresponding to the locked state shown in FIG. 11B) thereby preventing any further sliding of the first slider 505 relative to the rail base 503.

### Examples of Elastic Bumpers and Bolsters

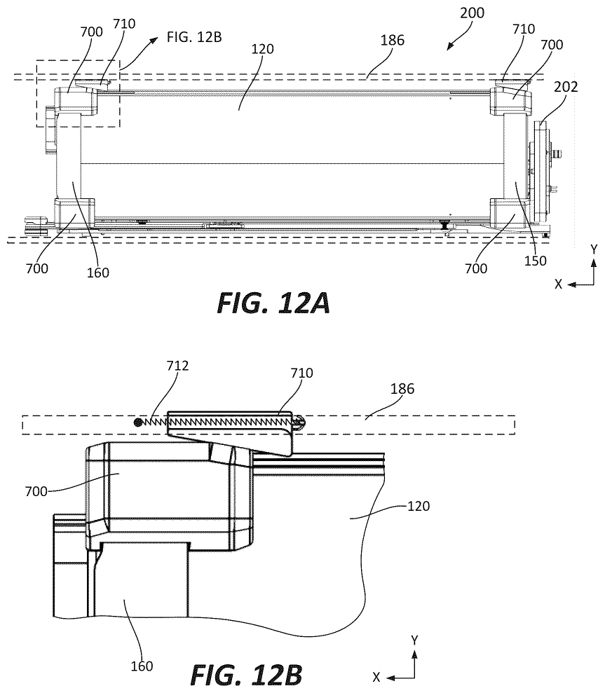

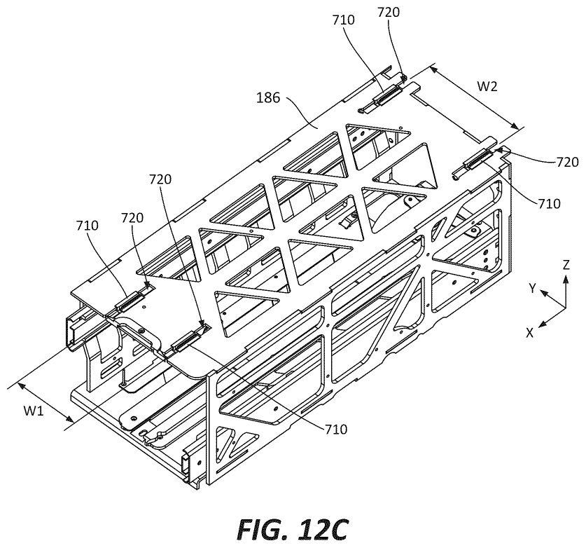

FIG. 12A illustrates a swappable battery module 120 positioned within enclosure 186 such that the swappable battery module 120 is connected to the docking unit 202. Specifically, the swappable battery module 120 comprises a first end plate 150 (facing and positioned proximate to the docking unit 202) and a second end plate 160 (facing away from the docking unit 202). During the operation of the battery dock 200 (e.g., when the battery dock 200 is a part of the electric vehicle 100), the enclosure 186 and the swappable battery module 120 may experience various vibrations/forces along any directions (e.g., when the electric vehicle 100 drives over rough terrain). Specifically, the transfer of forces between the swappable battery module 120 and the enclosure 186 needs to be as direct as possible and reduce the transfer through other components, which can be easily damaged by these loads (e.g., the charger 180/battery dock 200, module support rail 184, etc).

In some examples, the swappable battery module 120 comprises elastic bumpers 700 positioned at each corner of the swappable battery module 120, e.g., four elastic bumpers 700 on the first end plate 150 and four additional elastic bumpers 700 on the second end plate 160 (shown in FIGS. 12A and 12B). Elastic bumpers 700 may be made from rubber, silicone, polyurethane, neoprene, nitrile, ethylene propylene diene monomer (EPDM), and the like. Enclosure 186 comprises bolsters 710 that come into contact with at least some of the elastic bumpers 700 (e.g., the top four elastic bumpers 700). The bolsters 710 may be slidable (along the X-direction) relative to the plates of enclosure 186 that support these bolsters 710. For example, enclosure 186 may comprise slots 720 allowing the bolsters 710 to slide. Furthermore, the bolsters 710 may have a wedge shape (along the X-axis) such that contact is ensured between the elastic bumpers 700 and the corresponding bolsters 710. In some examples, each bolster 710 may be equipped with a spring 712 for biasing this bolster 710 relative to enclosure 186, e.g., away from the docking unit 202. This biasing ensures continuous contact between the bolsters 710 and the corresponding elastic bumpers 700 even when the swappable battery module 120 moves slightly relative to the enclosure 186.

As shown in FIG. 12C, the bolsters 710 (and the corresponding elastic bumpers 700) may be positioned at different widths (W1 and W2) thereby allowing the elastic bumpers 700 positioned on the first end plate 150 to clear the bolsters 710 designed to engage the elastic bumpers 700 positioned on the second end plate 160. In the illustrated example, the width (W1) between the bolsters 710 designed to engage the elastic bumpers 700 positioned on the first end plate 150 is less than the width (W2) between the bolsters 710 designed to engage the elastic bumpers 700 positioned on the second end plate 160. In another example, the width (W1) between the bolsters 710 designed to engage the elastic bumpers 700 positioned on the first end plate is greater than the width (W2) between the bolsters 710 designed to engage the elastic bumpers 700 positioned on the second end plate 160. In either example, the elastic bumpers 700 positioned on the first end plate 150 do not interfere with the bolsters 710 positioned further away from the docking unit 202 when the swappable battery module 120 is inserted or removed from the cavity formed by enclosure 186.

### Examples of Internal Flexible Supports

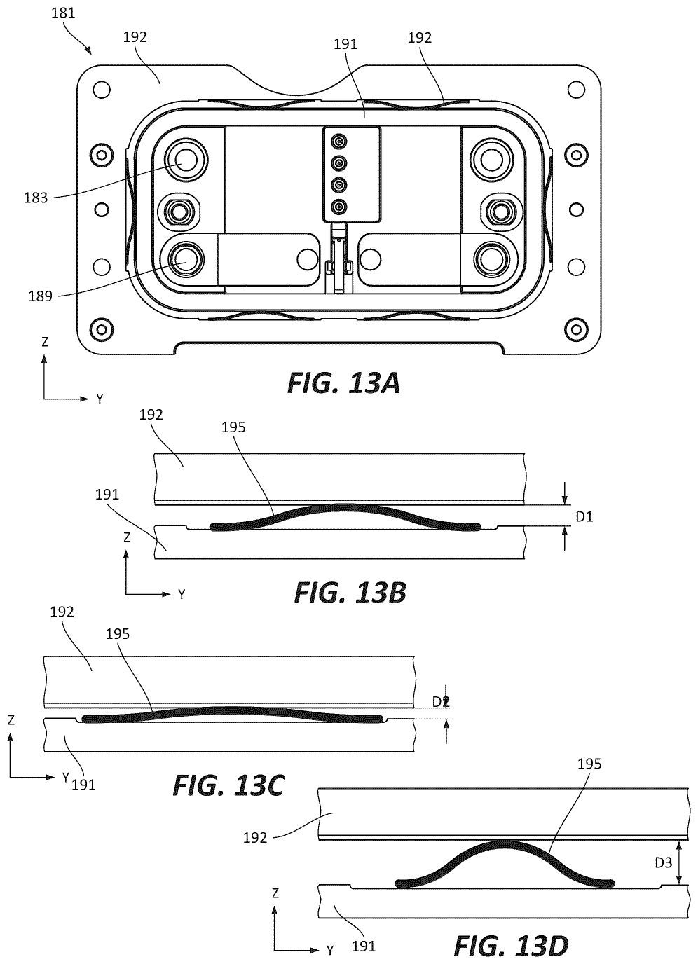

FIG. 13A is a schematic front view of dock base 181 that is used to make fluidic and electric connections to a swappable battery module 120 (not shown). The dock base 181 comprises an enclosure-attachment portion 192, which is rigidly attached to enclosure 186 (not shown) or, more specifically, to the structural frame of enclosure 186. As a result, the enclosure-attachment portion 192 moves together with the enclosure 186 or, more generally, with the rest of electric vehicle 100, e.g., any road bumps/vibrations are transferred through the enclosure 186 to the enclosure-attachment portion 192. These bumps/vibrations are highly undesirable to the fluidic and electric connections, especially in light of the mass/momentum of each swappable battery module 120. Specifically, these bumps/vibrations may cause mechanical damage to various components making these connections (e.g., dock fluidic ports 183 and dock electric terminals 189 as well as corresponding terminals on the battery module's side) resulting in fluid leaks, increased resistance of the electric connections, and/or loss of the connections.

In some examples, the dock base 181 comprises a connector-support portion 191, which is a separate/different component from the enclosure-attachment portion 192. The connector-support portion 191 is movably supported relative to the enclosure-attachment portion 192 by a set of flexible members 195 that allow a planar movement (in the Y-Z plane/perpendicular to the X axis) of the connector-support portion 191 and the enclosure-attachment portion 192 relative to each other as, e.g., is schematically shown by FIGS. 13B-13D. Therefore, when enclosure 186 and the enclosure-attachment portion 192 experience vehicle vibration (e.g., in either direction within the Y-Z plane), the set of flexible members 195 isolates (at least to some extent) the set of flexible members 195 from these vibrations. As such, the dock fluidic ports 183 and dock electric terminals 189 are isolated from the enclosure 186 and may move with the swappable battery module 120 (rather than the enclosure 186, when the swappable battery module 120 moves relative to the enclosure 186). As a result, the strain on the connections formed by the dock fluidic ports 183 and dock electric terminals 189 with the swappable battery module 120 is reduced during various movements of the electric vehicle 100. It should be noted that the X direction is the direction along which the connections are formed. The dock fluidic ports 183 and dock electric terminals 189 may have internal flexibility in this connection direction. Various examples of flexible members 195 are within the scope, e.g., leaf springs, compressible plastic units, and the like.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present examples are to be considered illustrative and not restrictive.

1. A method of operating a swappable battery module comprising a first electrical terminal, a second electrical terminal, a first fluidic port, and a second fluidic port, the method comprising:
positioning the swappable battery module on a battery dock comprising an enclosure, a module support rail slidably coupling the swappable battery module and the enclosure, a dock base attached to the enclosure and comprising dock electric terminals; and
sliding the swappable battery module on the module support rail toward the dock base until the first electrical terminal and the second electrical terminal are connected with the dock electric terminals, wherein:
the module support rail comprises a rail base, a first slider, and a second slider,
the rail base is fixed to the enclosure,
the second slider is detachably coupled to the swappable battery module, and
the first slider and the second slider move at different speeds or at a same speed relative to the dock base and the rail base depending on proximity of the swappable battery module to the dock base.

2. The method of claim 1, wherein the rail base comprises a rail-base slot defined by an engagement slot section and an extraction slot section, extending perpendicular to the engagement slot section.

3. The method of claim 2, wherein the engagement slot section comprises endpoints, operable as positive stops, and defines a closest position between the swappable battery module and the dock base.

4. The method of claim 2, wherein:
the module support rail further comprises a lever-based unit comprising bushings slidably fit into the rail-base slot,
when the bushings are in the engagement slot section, the first slider moves faster than the second slider, and
when the bushings are in the extraction slot section, the first slider and the second slider move at the same speed.

5. The method of claim 4, wherein, when the bushings are in the engagement slot section, the first slider moves at least twice as fast as the second slider.

6. The method of claim 4, wherein:
the lever-based unit comprises a first lever set and a second lever set,
the first lever set is connected to the bushings at a first end, pivotably connected to the first slider at a midpoint, and pivotably connected to the second lever set at a second end of the first lever set, opposite to the first end, and
the second lever set is pivotably connected to the first lever set and the first slider at opposite ends of the second lever set.

7. The method of claim 6, wherein:
the first lever set comprises a first lever and a second lever,
each of the first lever and the second lever comprises a first lever unit and a second lever unit spaced apart from each other and forming a gap c, and
the rail base partially extends into the gap c of each of the first lever and the second lever thereby restricting out-of-plane movement of each of the first lever and the second lever relative to the rail base.

8. The method of claim 7, wherein each of the first lever and a second lever rotatably support one of the bushings.

9. The method of claim 8, wherein each of the bushings comprises:
a stem protruding into round openings in each of the first lever and second lever, and
a collar that has a larger diameter than the stem and that extends into the gap between the first lever unit and the second lever unit.

10. The method of claim 9, wherein:
each of the first lever and the second lever comprises a band positioned between the first lever unit and the second lever unit and maintaining the gap c between the first lever unit and the second lever unit, and
the band surrounds a corresponding one of the bushings.

11. The method of claim 1, wherein:
the module support rail further comprises a locking mechanism configured to switch between a locked state and an unlocked state,
in the locked state, the locking mechanism allows the first slider to slide relative to the rail base, and
in the unlocked state, the locking mechanism prevents the first slider from sliding relative to the rail base.

12. The method of claim 11, wherein:
the locking mechanism comprises a lock support, a pivotable lock supported by the lock support, and an actuator configured to pivot the pivotable lock between the locked state and the unlocked state,
the rail base comprises a locking cavity facing the first slider,
in the locked state, the pivotable lock extends into the locking cavity, and
in the unlocked state, the pivotable lock is pulled from the locking cavity.

13. The method of claim 12, wherein the locking mechanism comprises a spring that biases the locking mechanism into the locked state.

14. The method of claim 11, wherein:
the module support rail comprises a rail handle,
the locking mechanism comprises an actuator, connected to the rail handle, and
pulling the rail handle, away from the dock base, switches the locking mechanism from the locked state to the unlocked state.

15. The method of claim 1, wherein:
the swappable battery module comprises a first end plate and a second end plate positioned on opposite sides of the swappable battery module, and
each of the first end plate and the second end plate comprises four elastic bumpers that directly interface the enclosure when the first electrical terminal and the second electrical terminal are connected with the dock electric terminals.

16. The method of claim 15, wherein:
the enclosure comprises bolsters directly interfacing at least two of the elastic bumpers on each of the first end plate and the second end plate, and
the bolsters are slidable along an axis parallel to a sliding direction of the swappable battery module on the module support rail.

17. The method of claim 16, wherein the bolsters are biased a direction away from the dock base.

18. The method of claim 15, wherein:
the dock base comprises a set of flexible members, a connector-support portion and an enclosure-attachment portion, movably attached to the enclosure-attachment portion by the set of flexible members,
the connector-support portion supports each of the first electrical terminal, the second electrical terminal, the first fluidic port, and the second fluidic port, and
the enclosure-attachment portion is rigidly attached to the enclosure.

19. The method of claim 18, wherein each flexible member in the set of flexible members is a leaf spring.

20. The method of claim 15, wherein the battery dock further comprises dock fluidic ports that are fluidically coupled with the first fluidic port and the second fluidic port when the first electrical terminal and the second electrical terminal are connected with the dock electric terminals.
